(19) United States
(12) Patent Application Publication
(10) Pub. No.: US 2025/0212660 A1
(43) Pub. Date: Jun. 26, 2025

(54) TRANSPARENT DISPLAY APPARATUS

(71) Applicant: LG Display Co., Ltd., Seoul (KR)

(72) Inventors: Hoiyong KWON, Paju-si (KR); Gyujae YOHN, Paju-si (KR)

(73) Assignee: LG Display Co., Ltd., Seoul (KR)

(21) Appl. No.: 18/910,978

(22) Filed: Oct. 9, 2024

(30) Foreign Application Priority Data
Dec. 26, 2023 (KR) 10-2023-0191422

(51) Int. Cl. H10K 59/80; H10K 59/131

(52) U.S. Cl. CPC H10K 59/874; H10K 59/131; H10K 59/873

(57) ABSTRACT

A transparent display apparatus according to an embodiment of the present disclosure includes a substrate including a display area on which a plurality of pixels are disposed and a non-display area adjacent to the display area, where each of the plurality of pixels has a transmissive portion and a plurality of sub-pixels. The transparent display apparatus further includes a plurality of dam areas extending from the non-display area to the display area on the substrate and partially surrounding the display area. The display area surrounded by each of the plurality of dam areas can include a plurality of moisture permeable bypass portions.

### CROSS-REFERENCE TO RELATED APPLICATION

This application claims priority to Korean Patent Applications No. 10-2023-0191422, filed in the Republic of Korea on Dec. 26, 2023, the entire contents of which are hereby expressly incorporated by reference into the present application.

### BACKGROUND

### Field of the Invention

This present disclosure relates to a transparent display device.

### Discussion of the Related Art

With the advancement of the information age, the demand for a display device for displaying an image has increased in various forms. Therefore, various types of display devices such as a liquid crystal display (LCD) device, a plasma display panel (PDP) device, an organic light emitting display (OLED) device and a quantum dot light emitting display (QLED) device have been recently used.

Further, studies for a transparent display apparatus in which a user can view objects or background positioned at an opposite side by transmitting the display apparatus are actively ongoing.

These transparent display apparatuses are highly likely to be used in various fields, as they can be used to view both the image and the background. Since the transparent display apparatus has various fields and uses to be applied, it needs to be manufactured in various types (or various sizes). However, when transparent display apparatuses are manufactured in various types (or various sizes), there can be a limitation of increasing manufacturing costs and production energy due to an increase the number of processes. In addition, when the transparent display apparatuses are manufactured in various types (or various sizes), they can be vulnerable to moisture permeation.

### SUMMARY OF THE DISCLOSURE

An aspect of the present disclosure is directed to providing a transparent display apparatus that can be manufactured in various types (or various sizes).

An aspect of the present disclosure is directed to providing a transparent display apparatus in which production energy can be reduced.

An aspect of the present disclosure is directed to providing a transparent display apparatus that can be manufactured in various types (or various sizes) and still have reduced or prevented moisture permeation.

An aspect of the present disclosure is directed to providing a transparent display apparatus that can reduce or prevent moisture permeation even when cut in different directions (or horizontally and perpendicularly).

The problems to be solved or addressed by the examples of the present disclosure are not limited to those mentioned above, and other problems not mentioned will be apparent to one of ordinary skill in the art to which the technical spirits of the present disclosure belong from the following description.

A transparent display apparatus according to an embodiment of the present disclosure comprises a substrate including a display area on which a plurality of pixels are disposed and a non-display area surrounding the display area, each of the plurality of pixels having a transmissive portion and a plurality of sub-pixels; and a plurality of dam areas extending from the non-display area to the display area on the substrate and partially surrounding the display area, wherein the display area surrounded by each of the plurality of dam areas comprises a plurality of moisture permeable bypass portions.

According to one or more aspect of the present disclosure, a transparent display apparatus can include a substrate including a display area on which a plurality of pixels and a non-display area surrounding the display area, each of the plurality of pixels having a transmissive portion and a plurality of sub-pixels; a dam area surrounding the display area on the substrate; and a plurality of moisture permeable bypass portions disposed in the display area surrounded by the dam area.

According to one or more aspect of the present disclosure, a transparent display apparatus can include a substrate including a display area on which a plurality of pixels are disposed and a non-display area adjacent to the display area, each of the plurality of pixels having a transmissive portion and a plurality of sub-pixels, wherein the display area comprises a plurality of moisture permeable bypass portions, the plurality of moisture permeable bypass portions being spaced apart from each other and at least partially overlapping in at least one of a first direction and a second direction different from the first direction.

The technical benefits of the present disclosure are not limited to the above-mentioned benefits, and other benefits, which are not mentioned above, can be clearly understood by those skilled in the art from the following descriptions.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a schematic top view of a transparent display device according to one embodiment of the present disclosure.

FIG. 2 is an enlarged top view of portion A shown in FIG. 1.

FIG. 3 is a schematic cross-sectional view cut along line I-I′ shown in FIG. 2.

FIG. 4 is an enlarged top view of a portion of the first display area in portion A shown in FIG. 1.

FIG. 5 is a schematic top view illustrating one example of a transparent display device according to a comparative example.

FIG. 6 is a schematic top view illustrating another example of a transparent display device according to a comparative example.

FIG. 7 is an enlarged top view of portion B shown in FIG. 1.

FIG. 8 is a schematic cross-sectional view cut along line II-II′ shown in FIG. 7.

FIG. 9 is an enlarged top view of a portion of the second display area in portion B shown in FIG. 1.

FIG. 10 is a schematic cross-sectional view cut along line III-III′ shown in FIG. 7.

FIG. 11 is a schematic cross-sectional view cut along line IV-IV′ shown in FIG. 7.

FIG. 12 is a schematic cross-sectional view cut along line V-V′ shown in FIG. 7.

FIG. 13 is an enlarged top view of C portion shown in FIG. 1.

FIG. 14 is a schematic top view of a transparent display device according to a second embodiment of the present disclosure.

FIG. 15 is a schematic top view of a transparent display device according to a third embodiment of the present disclosure.

FIG. 16 is a schematic top view of a transparent display device according to a fourth embodiment of the present disclosure.

FIG. 17 is a schematic top view of a transparent display device according to a fifth embodiment of the present disclosure.

### DETAILED DESCRIPTION OF THE EMBODIMENTS

Reference will now be made in detail to the embodiments of the present disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Further, the present disclosure is only defined by scopes of claims.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In a case where ‘comprise’, ‘have’, and ‘include’ described in the present specification are used, another part can be added unless ‘only’ is used. The terms of a singular form can include plural forms unless referred to the contrary.

In construing an element, the element is construed as including an error range although there is no explicit description.

In describing a position relationship, for example, when a position relation between two parts is described as ‘on’, ‘over’, ‘under’, and ‘next’, one or more other parts can be disposed between the two parts unless ‘just’ or ‘direct’ is used.

In describing a temporal relationship, for example, when the temporal order is described as “after,” “subsequent,” “next,” and “before,” a case which is not continuous can be included, unless “just” or “direct” is used.

It will be understood that, although the terms “first,” “second,” etc. can be used herein to describe various elements, these elements should not be limited by these terms. These terms are only used to distinguish one element from another and may not define order or sequence. For example, a first element could be termed a second element, and, similarly, a second element could be termed a first element, without departing from the scope of the present disclosure.

Further, “X-axis direction”, “Y-axis direction” and “Z-axis direction” should not be construed by a geometric relation only of a mutual vertical relation and can have broader directionality within the range that elements of the present disclosure can act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure can be partially or overall coupled to or combined with each other and can be variously inter-operated with each other and driven technically as those skilled in the art can sufficiently understand. The embodiments of the present disclosure can be carried out independently from each other or can be carried out together in co-dependent relationship.

Further, the term “can” encompasses all the meanings and coverages of the term “may.” The term “disclosure” is interchangeably used with, or encompasses all the meanings and coverages of, the term “invention.”

Hereinafter, various embodiments of the present disclosure will be described in detail with reference to the accompanying drawings. All the components of each display device or apparatus according to all embodiments of the present disclosure are operatively coupled and configured.

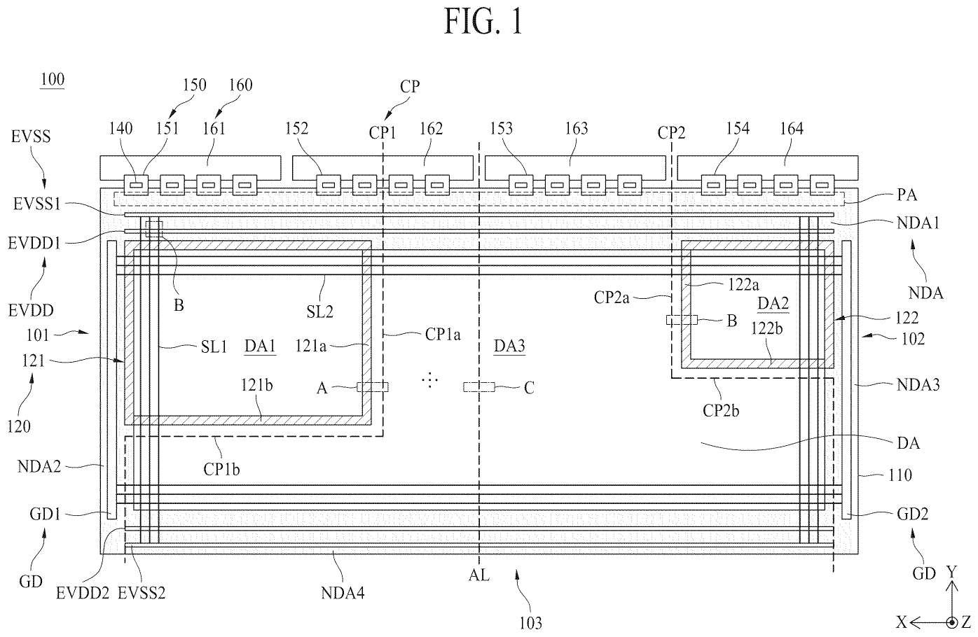

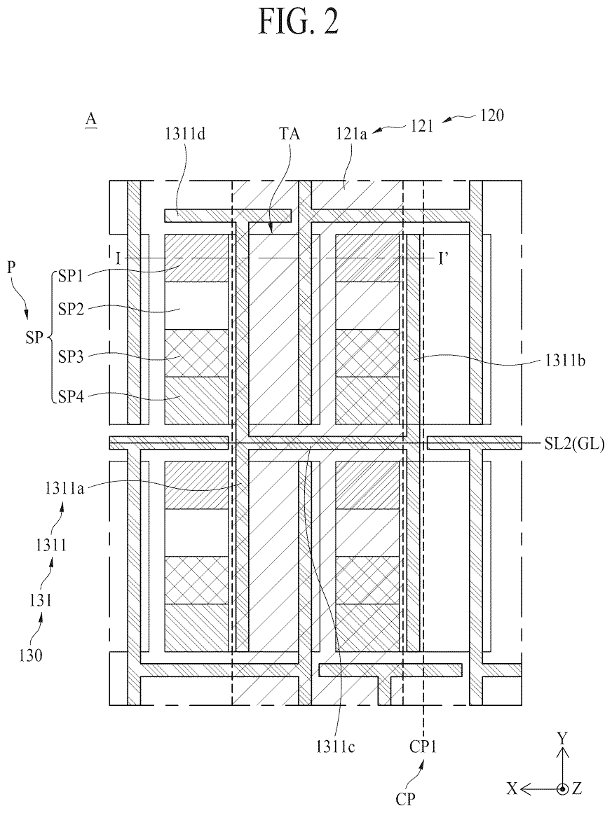

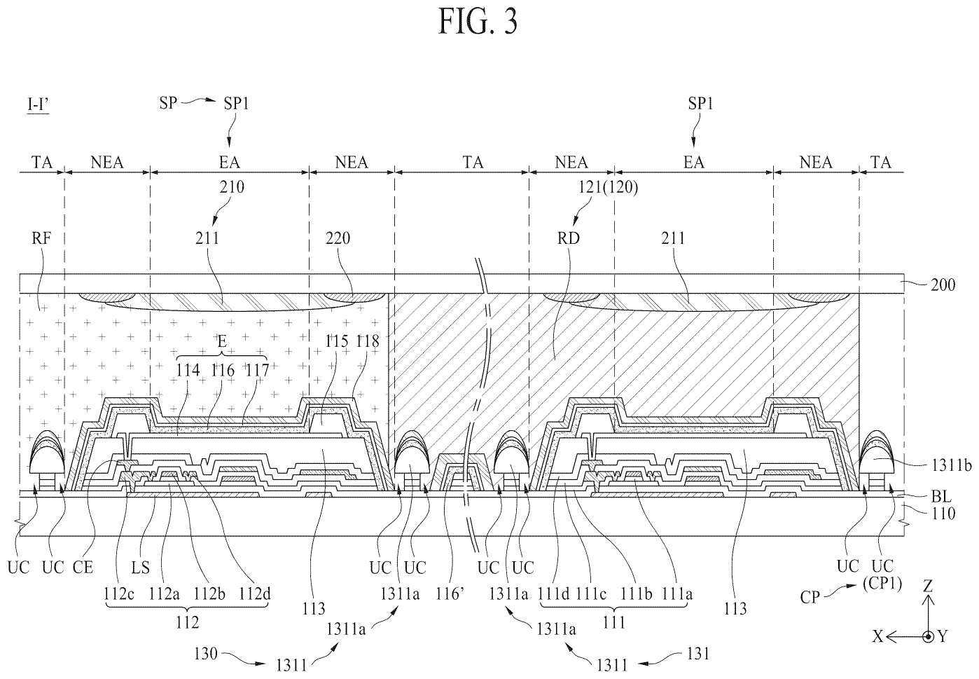

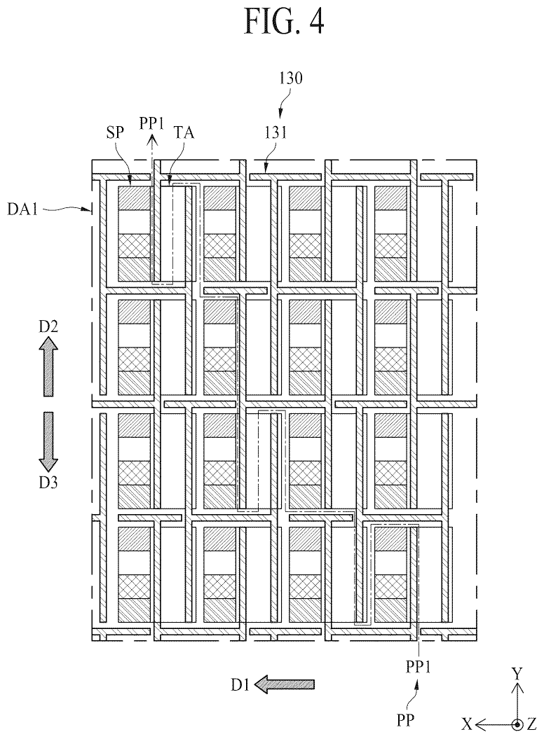

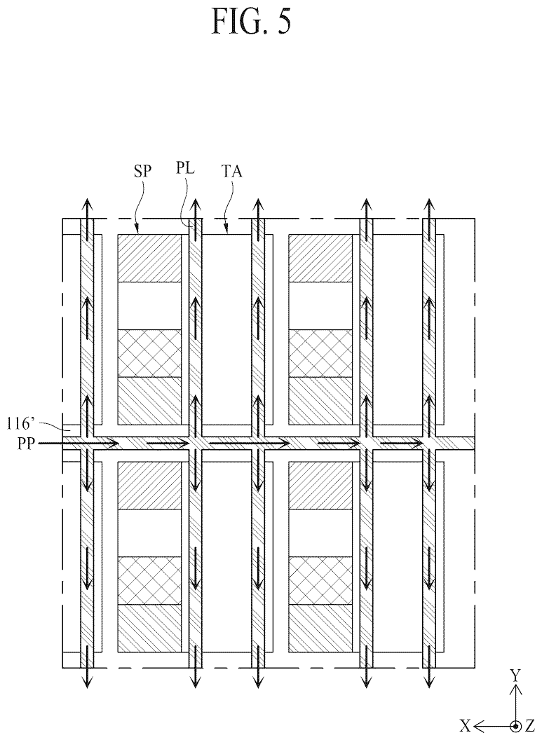

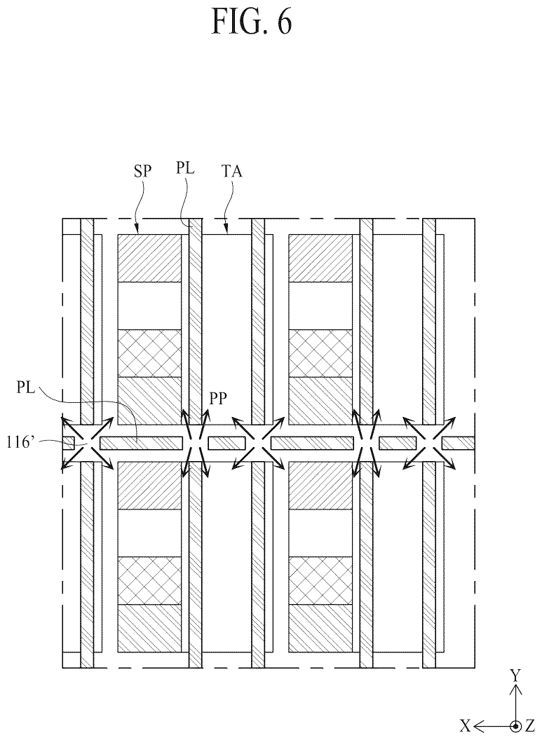

FIG. 1 is a schematic top view of a transparent display device according to one embodiment of the present disclosure, FIG. 2 is an enlarged top view of portion A shown in FIG. 1, FIG. 3 is a schematic cross-sectional view cut along line I-I′ shown in FIG. 2, FIG. 4 is an enlarged top view of a portion of the first display area in portion A shown in FIG. 1, FIG. 5 is a schematic top view illustrating one example of a transparent display device according to a comparative example, and FIG. 6 is a schematic top view illustrating another example of a transparent display device according to a comparative example.

In the following, the first direction (e.g., Y-axis direction) is a perpendicular direction, indicating a direction in which the first line SL1 (e.g., a data line) is extended, the second direction (e.g., X-axis direction) is a horizontal direction, indicating a direction in which the second line SL2 (e.g., a gate line GL) is extended, and the third direction (e.g., Z-axis direction) is a thickness direction of the transparent display apparatus 100.

Referring now to FIGS. 1 to 4, a transparent display apparatus 100 according to one embodiment of the present disclosure can include a substrate 110 provided with a display area DA and a non-display area NDA disposed adjacent to the display area DA, and a plurality of dam areas 120. A plurality of pixels P each having a transmissive portion TA and a plurality of sub-pixels SP can be disposed on the substrate 100. The plurality of dam areas 120 can be extended from the non-display area NDA to the display area DA and partially surrounding the display area DA on the substrate 110. Here, the display area DA surrounded by each of the plurality of dam areas 120 can include a plurality of moisture permeable bypass portions 130.

In one example, each of the plurality of dam areas 120 can be provided as a closed loop. Each of the plurality of dam areas 120 being provided as a closed loop can mean that the display area DA is partially surrounded by the dam areas 120, as shown in FIG. 1. Thus, the display area DA can be surrounded by the plurality of dam areas 120 having a closed structure, and can have a structure that is divided by cuts between the plurality of dam areas 120.

For example, as shown in FIG. 1, the transparent display apparatus 100 according to one embodiment of the present disclosure can include two dam areas 120, and can include two display areas DAs (or a first display area DA1 and a second display area DA2) having different areas (or sizes) by each of the dam areas 120. The dam area 120, according to one example, is a first area of the substrate 110, for example, a first dam area 121 disposed in the left area (or the bottom area) of FIG. 1, and a second area adjacent to the first area, for example, a second dam area 122 disposed in the right area (or the top area) of FIG. 1. Here, the substrate 110 can include a reference line AL disposed between the first area and the second area. The first area can have the same area as the second area with respect to the reference line AL. That is, the reference line AL can be disposed at half of the length in the second direction (x-axis direction) of the substrate 110.

Referring again to FIG. 1, the two display areas DA can include the first display area DA1 and the second display area DA2. Here, the first dam area 121 can be configured to surround the first display area DA1. The second dam area 122 can be configured to surround the second display area DA2. As a result, the display area DA can include the first display area DA1 surrounded by the first dam area 121, the second display area DA2 surrounded by the second dam area 122, and a third display area DA3 between the first display area DA1 and the second display area DA2. As shown in FIG. 1, the third display area DA3 can partially overlap the reference line AL.

On the other hand, the first display area DA1 (or the first dam area 121) and the second display area DA2 (or the second dam area 122) can be provided with different lengths in the first direction (Y-axis direction) (or the perpendicular direction) and the second direction (X-axis direction) (or the horizontal direction), respectively. Thus, the transparent display apparatus 100 according to one embodiment of the present disclosure can be divided into two transparent display devices having different areas (or sizes) when a cut is made between the two dam areas 120. For example, the transparent display apparatus 100 according to one embodiment of the present disclosure can be divided into a first transparent display apparatus 101 having a first area, and a second transparent display apparatus 102 having a second area smaller than the first area. Thus, the transparent display apparatus 100 according to one embodiment of the present disclosure can be provided with the plurality of dam areas 120 such that the display panel can be cut into various sizes, and thus can be provided to be manufactured in various types (or various sizes). The display panel can comprise the substrate 110 and an opposing substrate 200 that is facing and bonded to the substrate 110.

The two transparent display devices having different areas (or sizes) can be provided as a cutting device such as a laser or a wheel cuts the substrate 110 (or the display panel) along the cutting lines disposed in two directions, for example, in the first direction (Y-axis direction) and the second direction (X-axis direction). Thus, the transparent display apparatus 100 according to one embodiment of the present disclosure can further comprise a cutting portion CP that is cut by the cutting device. As shown in FIG. 1, the cutting portion CP according to one example can include a first cutting portion CP1 disposed partially along an edge of the first dam area 121, and a second cutting portion CP2 disposed partially along an edge of the second dam area 122.

The first cutting portion CP1 according to one example can include a first cutting line CP1a disposed in a first direction (Y-axis direction) and a second cutting line CP1b disposed in a second direction (X-axis direction) different from the first direction (Y-axis direction). The first cutting line CP1a can be disposed adjacent to a first side 121a of the dam area 120 (or the first dam area 121). In one example, the first side 121a is a side disposed in a perpendicular direction with respect to FIG. 1. The second cutting line CP1b can be disposed adjacent to a second side 121b of the dam area 120 (or the first dam area 121). In one example, the second side 121b is a side disposed in a horizontal direction with respect to FIG. 1.

The second cutting portion CP2, according to one example, can include a first cutting line CP2a disposed in the first direction (Y-axis direction) and a second cutting line CP2b disposed in the second direction (X-axis direction) different from the first direction (Y-axis direction). The first cutting line CP2a can be disposed adjacent to a first side 122a of the dam area 120 (or the second dam area 122). In one example, the first side 122a is a side disposed in a perpendicular direction with respect to FIG. 1. The second cutting line CP2b can be disposed adjacent to a second side 122b of the dam area 120 (or the second dam area 122). In one example, the second side 122b is a side disposed in a horizontal direction with respect to FIG. 1.

The first cutting line CP1a of the first cutting portion CP1 and the first cutting line CP2a of the second cutting portion CP2 are identical in that they are disposed in a direction parallel to the first direction (Y-axis direction), but differ in that they have different lengths. For example, the first cutting line CP1a of the first cutting portion CP1 can be provided to have a longer length than the first cutting line CP2a of the second cutting portion CP2.

The second cutting line CP1b of the first cutting portion CP1 and the second cutting line CP2b of the second cutting portion CP2 are identical in that they are disposed in a direction parallel to the second direction (X-axis direction), but differ in that they have different lengths. For example, the second cutting line CP1b of the first cutting portion CP1 can be provided to have a longer length than the second cutting line CP2b of the second cutting portion CP2.

A transparent display apparatus 100 according to one embodiment of the present disclosure is configured that the first transparent display apparatus 101 is manufactured as the cutting devices cut a substrate 110 (or display panel) along the first cutting line CP1a and the second cutting line CP1b which are disposed in different directions. A transparent display apparatus 100 according to one embodiment of the present disclosure is configured so that the second transparent display apparatus 102 is manufactured as the cutting devices cut the substrate 110 (or display panel) along the first cutting line CP2a and the second cutting line CP2b which are disposed in different directions.

Accordingly, the transparent display apparatus 100 according to one embodiment of the present disclosure can be provided with the cutting portion CP that is cut by cutting devices without an additional masking process, thereby reducing production energy compared to a transparent display apparatus produced in various types (or various sizes) through various production processes (or manufacturing processes).

Even if the transparent display apparatus 100 according to one embodiment of the present disclosure is divided into first and second transparent display devices 101, 102, moisture permeation can be reduced or prevented because the dam area 120 covers the edges of each of the first and second transparent display devices 101, 102 with a closed-loop structure (or a closed structure). Thus, even though the transparent display apparatus 100 according to one embodiment of the present disclosure is cut (or divided) into a plurality of transparent display apparatuses, the reliability of each of the plurality of transparent display apparatuses against moisture permeation can be improved.

On the other hand, in the transparent display apparatus 100 according to one embodiment of the present disclosure, the cutting portion CP is not formed in the gate driver GD because, if the gate driver GD is damaged, the first transparent display apparatus 101 (or the second transparent display apparatus 102) cannot be operated. Therefore, the cutting portion CP can be provided in a position where the gate driver GD is not damaged.

In the transparent display apparatus 100 according to one embodiment of the present disclosure, the display area DA (or the first display area DA1 and the second display area DA2) surrounded by each of the plurality of dam areas 120 can include the plurality of moisture permeable bypass portions 130. Each of the plurality of moisture permeable bypass portions 130 according to one example can be provided to be an island shape. The plurality of moisture permeable bypass portions 130 can make the amount of moisture and/or oxygen permeation into the interior of the dam area 120 stochastically lowered.

Referring to FIG. 2, the plurality of moisture permeable bypass portions 130 can include a plurality of first moisture permeable bypass portions 131 disposed in the first display area DA1. Each of the plurality of first moisture permeable bypass portions 131 can be disposed in an island shape, thus they are spaced apart from each other. For example, each of the plurality of first moisture permeable bypass portions 131 can be configured as a combination of a “T” and a right lying “T”. Each of the plurality of first moisture permeable bypass portions 131 can have a shape of a combination of two “T”s, and thus can be expressed in terms of a double “T”.

The transparent display apparatus 100 according to one embodiment of the present disclosure has a plurality of first moisture permeable bypass portions 131 spaced apart from each other, thus moisture and oxygen from the outside can be prevented from permeating through the first moisture permeable bypass portions 131. Further, as shown in FIG. 2, the transparent display apparatus 100 according to one embodiment of the present disclosure is provided that the plurality of first moisture permeable bypass portions 131 are disposed spaced apart from each other and overlap in at least one of the first direction (Y-axis direction) and the second direction (X-axis direction) different from the first direction (Y-axis direction), thus the pathway for external moisture and oxygen to penetrate through an organic layer (e.g., a disconnected organic emitting layer 116′, shown in FIG. 3) between each of the plurality of first moisture permeable bypass portions 131 can lengthen. Accordingly, the transparent display apparatus 100 according to one embodiment of the present disclosure can be prevented from moisture permeation due to the plurality of moisture permeable bypass portions 130, or the path for moisture permeation can be lengthened, thereby improving reliability.

Hereinafter, with reference to FIGS. 1 to 3, the transparent display apparatus 100 according to one embodiment of the present disclosure will be described in more detail.

Referring to FIG. 1, the transparent display apparatus 100 according to one embodiment of the present disclosure can include a source drive integrated circuit (hereinafter IC) 140, a flexible film 150, and a plurality of circuit boards 160, and a display panel including a substrate 110 having the plurality of gate drivers GDs. The plurality of circuit boards 160 can be connected to a timing controller via cables.

The display panel can include a substrate 110 and an opposite substrate 200 (shown in FIG. 3).

The substrate 110 can include a thin film transistor, and can be a transistor array substrate, a lower substrate, a base substrate, or a first substrate. The substrate 110 can be a transparent glass substrate or a transparent plastic substrate. For example, the substrate 110 can be a transparent glass substrate. Hereinafter, the substrate 110 will be defined as a first substrate.

The opposing substrate 200 can be facing and bonded to the first substrate 110 via a connection member RD (shown in FIG. 3) and a filling member RF (shown in FIG. 3). For example, the opposing substrate 200 can have a smaller size than the first substrate 110 and can be facing and bonded to a portion of the first substrate 110 except the pad portion. The opposing substrate 200 can be an upper substrate, a second substrate, or an envelope substrate. The opposing substrate 200 can be bonded to the first side of the first substrate 110 by a substrate bonding process mediated by an adhesive member. Hereinafter, the opposing substrate 200 is defined as the second substrate.

The transparent display apparatus 100 according to one embodiment of the present disclosure can further comprise the connection member RD and the filling member RF.

The dam area 120, according to one example, can include the connecting member RD. The connection member RD can be disposed between the first substrate 110 and the second substrate 200. Accordingly, the first substrate 110 and the second substrate 200 can be facing and bonded to each other via the connection member RD. For example, the connection member RD can comprise a thermosetting transparent adhesive or a light-curable transparent adhesive. The connecting member RD can include an absorbent material for absorbing external moisture or humidity that permeates to the display area DA.

The connecting members RD of the dam area 120, according to one example, can be disposed in the non-display area NDA and extending from the non-display area NDA to the display area DA. As shown in FIG. 3, the connection member RD can be disposed to fill a gap between the first substrate 110 and the second substrate 200 in the dam area 120. Accordingly, the connecting member RD can prevent moisture or the like from permeating to the display area DA through the gap between the first substrate 110 and the second substrate 200.

The filling member RF can be disposed adjacent to the connecting member RD. The filling member RF can be disposed to fill a gap between the first substrate 110 and the second substrate 200, thereby supporting the first substrate 110 and the second substrate 200. Thus, the filling member RF can prevent the first substrate 110 and the second substrate 200 from being easily deformed by an external force.

On the other hand, the filling member RF or the connecting member RD can be disposed between an organic emitting layer 116 formed on the first substrate 110 and the second substrate 200 to prevent external moisture or humidity permeating through the second substrate 200 from reaching the organic emitting layer 116. In other words, each of the filling member RF and the connecting member RD can have a barrier function to prevent moisture permeation. Each of the filling member RF and the connecting member RD can further include an absorbent material to absorb water or moisture to increase the moisture barrier effect. For example, the absorbent material can be a getter.

On the other hand, the filling member RF can comprise a thermosetting transparent adhesive or a light-curable transparent adhesive. In this case, the filling member RF can be utilized to bond the first substrate 110 and the second substrate 200 together with the connection member RD. Thus, the bonding force of the first substrate 110 and the second substrate 200 can be further improved. Since each of the plurality of dam areas 120 partially surrounds the display area DA, the filling member RF can be disposed to be surrounded by the connecting member RD. The connection members RD can overlap the plurality of pixels P by being partially disposed in the display area DA.

The connecting member RD according to one example can comprise an opaque material but is not necessarily limited thereto and can comprise a transparent material. The filling member RF according to one example is disposed in the display area DA, so it can comprise a transparent material to improve the transmittance of the light emitted.

Referring again to FIG. 1, the gate driver GD supplies gate signals to the gate lines in accordance with the gate control signal input from the timing controller. When the source drive IC 140 is manufactured as a driving chip, the source drive IC 140 can be packaged in the flexible film 150 in a chip on film (COF) method or a chip on plastic (COP) method.

Pads, such as power pads, data pads, can be formed in the non-display area of the display panel. Lines connecting the pads with the source drive IC 140 and lines connecting the pads with lines of the circuit board 160 can be formed in the flexible film 150. The flexible film 150 can be attached onto the pads by using an anisotropic conducting film, whereby the pads can be connected with the lines of the flexible film 150.

The first substrate 110 according to an example can include a display area DA and a non-display area NDA.

The display area DA is an area where an image is displayed, and can be a pixel array area, an active area, a pixel array unit, a display unit, or a screen. For example, the display area DA can be disposed at a central portion of the display panel (or the first substrate 110).

The display area DA according to an example can include gate lines, data lines, pixel driving power lines, and a plurality of pixels P. Each of the plurality of pixels P can include a plurality of sub-pixels SP and the transmissive portion TA (shown in FIG. 2). The plurality of sub-pixels SP can be defined by the gate lines and the data lines. The transmissive portion TA is disposed adjacent to the plurality of sub-pixels SP. The transmissive portion TA is an area configured to allow light to transmit through the front and back sides of the display panel. Thus, a user positioned at the front side of the display panel can view an image, background, or the like positioned at the back side of the display panel through the transmissive portion TA.

Referring to FIG. 2, each of the plurality of sub-pixels SP can be defined as an area of the smallest unit in which actual light is emitted.

According to one example, at least four sub-pixels SP disposed adjacent to each other among the plurality of sub-pixels SP, and one transmissive portion TA comprise one unit pixel P. The one unit pixel can include a red pixel, a green pixel, a blue pixel, a white pixel, and the transmissive portion TA, but is not limited to. In one example, the one unit pixel can comprise at least one red pixel, at least one green pixel, at least one blue pixel, at least one white pixel, and at least one transmissive portion TA.

In another example, three sub-pixels SPs disposed adjacent to each other among the plurality of sub-pixels SPs, and one transmissive portion TA comprise one unit pixel. The one unit pixel can include, but is not limited to, at least one red pixel, at least one green pixel, at least one blue pixel, and one transmissive portion TA.

Each of the plurality of sub-pixels SPs can include a thin film transistor, and a light emitting portion connected to the thin film transistor. The light emitting portion can include a light emitting element layer (or the organic emitting layer) interposed between the anode electrode (or first electrode) and the cathode electrode (or second electrode).

The light emitting element layers respectively disposed in the plurality of subpixels SP can individually emit light of their respective colors different from one another or commonly emit white light. According to an example, when the light emitting element layers of the plurality of subpixels SP commonly emit white light, each of the red subpixel, the green subpixel and the blue subpixel can include a color filter (or wavelength conversion member) for converting white light into light of its respective different color. In this case, the white subpixel according to an example can not include a color filter. In the transparent display apparatus 100 according to one embodiment of the present disclosure, the red sub-pixel can be a first sub-pixel SP1, the white sub-pixel can be a second sub-pixel SP2, the green sub-pixel can be a third sub-pixel SP3, and the blue sub-pixel can be a fourth sub-pixel SP4.

Each of the subpixels SP supplies a predetermined current to the organic light emitting element in accordance with a data voltage of the data line when a gate signal is input from the gate line by using the thin film transistor. For this reason, the light emitting portion of each of the subpixels can emit light with a predetermined brightness in accordance with the predetermined current. A structure of each of the subpixels SP will be described later with reference to FIG. 3.

The non-display area NDA can be an area where an image is not displayed, and can be a peripheral circuit area, a signal supply area, a non-active area, or a bezel area. The non-display area NDA can be configured to be around the display area DA. That is, the non-display area NDA can be disposed to surround the display area DA.

The transparent display apparatus 100 according to one embodiment of the present disclosure can include a plurality of gate drivers GDs disposed in the non-display area NDA. The plurality of gate drivers GDs can be disposed parallel to the first direction (Y-axis direction) or the second direction (X-axis direction). The transparent display apparatus 100 according to one embodiment of the present disclosure is described by way of example in which the plurality of gate drivers GDs are disposed to be extended in the first direction (Y-axis direction).

As shown in FIG. 1, the plurality of gate drivers GDs can be disposed in the first direction (Y-axis direction) in the non-display area NDA. The plurality of gate drivers GDs can be disposed in parallel with the display area DA interposed therebetween.

Each of the plurality of gate drivers GDs supplies gate signals to the gate lines according to gate control signals input from the timing controller connected to the plurality of circuit boards 160. Each of the plurality of gate drivers GDs can be formed in a gate driver in panel GIP manner in the non-display area NDA on either outer side of the display area DA, as shown in FIG. 1. Alternatively, the plurality of gate drivers GD can be made of a driving chip, mounted on a flexible film, and attached to the non-display areas NDA on both outer sides of the display area DA of the display panel by a TAB (tape automated bonding) method. The gate driver GD according to one example can include a plurality of gate driver circuits (or GIP circuits) and a plurality of GIP wiring. The GIP wiring, in one example, can include a plurality of signal wiring and a plurality of power wiring.

The plurality of gate drivers GDs can be disposed separately on the left side of the display area DA, i.e., the second non-display area NDA2, and on the right side of the display area DA, i.e., the third non-display area NDA3. According to one example, a plurality of gate drivers GD can be connected to the plurality of pixels P and the plurality of wiring (or a plurality of second lines SL2) for supplying power and/or signals to each of the plurality of pixels P. As shown in FIG. 1, the transparent display apparatus 100 according to one embodiment of the present disclosure can further include a plurality of first lines SL1 intersecting with the plurality of second lines SL2.

The plurality of second lines SL2 can extend in a second direction (X-axis direction). Each of the plurality of second lines SL2 can include at least one gate line GL (or scan line GL). The second direction (X-axis direction) can refer to a direction in parallel to the gate line GL.

In the following, when the second line SL2 comprises a plurality of lines, one second line SL2 can refer to a group of signal lines comprising a plurality of lines. For example, when the second line SL2 includes two scan lines, one second line SL2 can refer to a group of signal lines comprising two scan lines.

The plurality of first lines SL1 can extend in the first direction (Y-axis direction). The plurality of first lines SL1 can intersect with the plurality of second lines SL2. Each of the plurality of first lines SL1 can be connected to at least one of a plurality of pads, a pixel power shorting bar EVDD, and a common power shorting bar EVSS disposed in a first non-display area NDA1. The pixel power supply shorting bar EVDD and the common power supply shorting bar EVSS can be disposed in the first non-display area NDA1 disposed between the pad area PA and the display area DA with respect to the display area DA, and in a fourth non-display area NDA4 disposed to face the pad area PA. The first direction (X-axis direction) can be a direction in parallel to the data line.

The pixel-powered shorting bar EVDD can include a first pixel-powered shorting bar EVDD1 disposed in the first non-display area NDA1, and a second pixel-powered shorting bar EVDD2 disposed in the fourth non-display area NDA4. The first pixel power shorting bar EVDD1 and the second pixel power shorting bar EVDD2 can be disposed in parallel to the second direction (X-axis direction) with the display area DA interposed therebetween.

The common power supply shorting bar EVSS can include a first common power supply shorting bar EVSS1 disposed in the first non-display area NDA1, and a second common power supply shorting bar EVSS2 disposed in the fourth non-display area NDA4. The first common power supply shorting bar EVSS1 and the second common power supply shorting bar EVSS2 can be disposed in parallel to the second direction (X-axis direction) with the display area DA interposed therebetween. According to an example, the first common power supply shorting bar EVSS1 and the second common power supply shorting bar EVSS2 can be disposed closer to the edge of the first substrate 110 than the first pixel power supply shorting bar EVDD1 and the second pixel power supply shorting bar EVDD2

The plurality of first lines SL1 can include a pixel power line connected to the pixel power shorting bar EVDD and a common power line connected to the common power shorting bar EVSS. In one embodiment, the plurality of first lines SL1 can further include a plurality of data lines and reference lines.

Hereinafter, when the first line SL1 includes a plurality of lines, one first line SL1 can refer to a signal line group consisting of a plurality of lines. For example, when the first line SL1 includes two data lines, the pixel power line, the common power line, and the reference line, one first line SL1 can refer to a group of signal lines comprising two data lines, the pixel power line, the common power line, and the reference line.

The pixels P are disposed to overlap with at least one of the first line SL1 and the second line SL2, and emit a predetermined light to display an image. The light emission area EA can correspond to an area in which the pixels P emit light.

Referring to FIG. 2, each of the pixels P can include a first sub-pixel SP1, a second sub-pixel SP2, a third sub-pixel SP3, and a fourth sub-pixel SP4. The first sub-pixel SP1 can be configured to include a first light emission area EA emitting red light, the second sub-pixel SP2 can be configured to include a second light emission area emitting white light, the third sub-pixel SP3 can be configured to include a third light emission area emitting green light, and the fourth sub-pixel SP4 can be configured to include a fourth light emission area emitting blue light. In FIG. 2, the first to fourth sub-pixels SP1, SP2, SP3, SP4 included in the one pixel P are illustrated as being disposed in the first direction (Y-axis direction), but the arrangement order of each of the sub-pixels SP1, SP2, SP3, SP4 can be varied.

Since the transparent display apparatus 100 according to one embodiment of the present disclosure is configured that the light emitting element emits white light, thus the second sub-pixel SP2, which is a white sub-pixel as shown in FIG. 2, can not be provided with a color filter. On the other hand, the first sub-pixel SP1 can be provided with a red color filter 210, shown in FIG. 3, thus red light is emitted, the third sub-pixel SP3 can be provided with a green color filter so that green light is emitted, and the fourth sub-pixel SP4 can be provided with a blue color filter so that blue light is emitted.

Hereinafter, with reference to FIGS. 2 and 3, the pixel P of the transparent display apparatus 100 according to one embodiment of the present disclosure will be described.

Referring to FIGS. 2 and 3, each of the plurality of pixels P provided in the display area DA can include the plurality of sub-pixels SP and the transmissive portion TA. The transmissive portion TA can be disposed adjacent to each of the plurality of sub-pixels SP, as shown in FIG. 2. As shown in FIG. 3, the connection member RD can be disposed in the sub-pixels SP disposed in the dam area 120. Also, the filling member RF can be disposed in the sub-pixels SP disposed in the display area DA other than the dam area 120. However, as shown in FIG. 3, both the filling member RF and the connecting member RD can not be disposed in the area where the cutting portion CP is disposed. Since the transparent display apparatus 100 according to one embodiment of the present disclosure is provided so that both the filling member RF and the connecting member RD are not formed in the cutting portion CP. Therefore, the transparent display apparatus 100 according to one embodiment of the present disclosure not only can the manufacturing cost be reduced due to material savings, but also the defect rate can be reduced since the area in which the filling member RF and the connecting member RD are not disposed is cut, and thus cutting can be facilitated.

Referring again to FIG. 3, each of the plurality of sub-pixels SPs can be disposed on the first substrate 110 and can include a buffer layer BL to prevent moisture permeation to the thin film transistors 112.

Further, each of the sub-pixels SPs according to one embodiment of the present disclosure comprises an inorganic layer 111, a planarization layer 113 provided on the inorganic layer 111, an anode electrode 114 (or first electrode 114) provided on the planarization layer 113, a bank 115, the organic emitting layer 116, a cathode electrode 117 (or second electrode 117), and an encapsulation layer 118. The inorganic layer 111 is provided on an upper surface of the buffer layer BL and includes a gate insulating layer 111a, an interlayer insulating layer 111b, a first passivation layer 111c, and a second passivation layer 111d.

The inorganic layer 111 can be disposed with thin-film transistors 112 for driving the sub-pixels SP. The inorganic layer 111 can also be expressed in terms of a circuit element layer. A buffer layer BL can be included in the inorganic layer 111 along with the gate insulating layer 111a, the interlayer insulating layer 111b, the first passivation layer 111c, and the second passivation layer 111d. The anode electrode 114, the organic emitting layer 116, and the cathode electrode 117 can be included in the light emitting element.

The buffer layer BL can be formed between the first substrate 110 and the gate insulating layer 111a to protect the thin film transistor 112. Between the buffer layer BL and the first substrate 110, a pixel power line EVDD or a wiring LS electrically connected to the pixel power line EVDD can be disposed. The buffer layer BL can be disposed entirely on one surface (or front surface) of the first substrate 110. The buffer layer BL can serve to prevent a material contained in the first substrate 110 from being diffused into a transistor layer during a high temperature process of the manufacturing process of the thin film transistor. Optionally, the buffer layer BL can be omitted as the case can be.

The thin film transistor 112 according to an example can include an active layer 112a, a gate electrode 112b, a source electrode 112c, and a drain electrode 112d.

The active layer 112a can include a channel area, a drain area and a source area, which are formed in a thin film transistor area of a circuit area of the pixel P. The drain area and the source area can be spaced apart from each other with the channel area interposed therebetween.

The active layer 112a can be formed of a semiconductor material based on any one of amorphous silicon, polycrystalline silicon, oxide and organic material.

The gate insulating layer 111a can be formed on the channel area of the active layer 112a. As an example, the gate insulating layer 111a can be formed in an island shape only on the channel area of the active layer 112a, or can be formed on an entire front surface of the first substrate 110 or the buffer layer BL, which includes the active layer 112a.

The gate electrode 112b can be formed on the gate insulating layer 111a to overlap the channel area of the active layer 112a.

The interlayer insulating layer 111b can be formed on the gate electrode 112b and the drain area and the source area of the active layer 112a. The interlayer insulating layer 111b can be formed in the circuit area and an entire light emission area, in which light is emitted to the pixel P. For example, the interlayer insulating layer 111b can be made of an inorganic material, but is not necessarily limited thereto.

The source electrode 112c can be electrically connected to the source area of the active layer 112a through a source contact hole provided in the interlayer insulating layer 111b overlapped with the source area of the active layer 112a. Further, the source electrode 112c can be connected to the wiring LS electrically connected to the pixel power line EVDD through contact holes provided in the interlayer insulating layer 111b and the buffer layer BL that do not overlap with the source area of the active layer 112a. The source electrode 112c can be connected to the anode electrode 114 via a connection electrode CE penetrating the first passivation layer 111c.

The drain electrode 112d can be electrically connected to the drain area of the active layer 112a through a drain contact hole provided in the interlayer insulating layer 111b overlapped with the drain area of the active layer 112a.

The drain electrode 112d and the source electrode 112c can be made of the same metal material. For example, each of the drain electrode 112d and the source electrode 112c can be made of a single metal layer, a single layer of an alloy or a multi-layer of two or more layers, which is the same as or different from that of the gate electrode.

In addition, the circuit area can further include first and second switching thin film transistors disposed together with the thin film transistor 112, and a capacitor. Since each of the first and second switching thin film transistors is provided on the circuit area of the pixel P to have the same structure as that of the thin film transistor 112, its description will be omitted. The capacitor can be provided in an overlap area between the gate electrode 112b and the source electrode 112c of the thin film transistor 112, which overlap each other with the interlayer insulating layer 111b interposed therebetween.

Additionally, in order to prevent a threshold voltage of the thin film transistor provided in a pixel area from being shifted by light, the display panel or the first substrate 110 can further include a light shielding layer provided below the active layer 112a of at least one of the thin film transistor 112, the first switching thin film transistor or the second switching thin film transistor. The light shielding layer can be disposed between the first substrate 110 and the active layer 112a to shield light incident on the active layer 112a through the first substrate 110, thereby minimizing a change in the threshold voltage of the transistor due to external light.

The first passivation layer 111c can be disposed between the first substrate 110 and the planarization layer 113. The first passivation layer 111c, according to one example, covers a drain electrode 112d and the source electrode 112c of the thin film transistor 112 and the interlayer insulating layer 111b. The first passivation layer 111c can be formed throughout the circuit area and the light emission area.

The second passivation layer 111d can be provided on the first substrate 110 to cover the pixel (or the light emission area EA). For example, the second passivation layer 111d can be provided to cover the connection electrode CE between the first passivation layer 111c and the planarization layer 113. The first passivation layer 111c can be formed throughout the circuit area and the light emission area.

The planarization layer 113 can be provided on the first substrate 110 to cover the second passivation layer 111d. When the second passivation layer 111d is omitted, the planarization layer 113 can be provided on the first substrate 110 to cover the circuit area. The planarization layer 113 can be formed throughout the circuit area and the light emission area. Further, the planarization layer 113 can be formed throughout the display area DA and the non-display area NDA except for the pad area PA. For example, the planarization layer 113 can include an extension (or extensions) extending from the display area DA toward the rest of the non-display area NDA except for the pad area PA. Thus, the planarization layer 113 can have a relatively larger size than the display area DA.

The planarization layer 113 according to an example can be formed to be relatively thick, and thus can provide a flat surface on the display area DA and the non-display area NDA. For example, the planarization layer 113 can be made of an organic material such as photo acryl, benzocyclobutene, polyimide, and fluorine resin.

The anode electrodes 114 of the sub-pixels SP can be formed on the planarization layer 113. The anode electrode 114 is connected to the source electrode or the drain electrode of the thin film transistor 112 by being connected to the connection electrode CE through the contact hole through the planarization layer 113 and the second passivation layer 111d.

The anode electrode 114 can be made of at least one of a transparent metal material, a semi-transmissive metal material, or a metal material having high reflectance.

When the transparent display apparatus 100 is provided in a top emission mode, the anode electrode 114 can be formed of a metal material having high reflectance or a stacked structure of a metal material having high reflectance and a transparent metal material. For example, the anode electrode 114 can be formed of a metal material having high reflectance, such as a stacked structure (Ti/Al/Ti) of aluminum and titanium, a stacked structure (ITO/Al/ITO) of aluminum and ITO, an Ag alloy, and a stacked structure (ITO/Ag alloy/ITO) of Ag alloy and ITO. The Ag alloy can be an alloy such as silver (Ag), palladium (Pd), and copper (Cu).

When the transparent display apparatus 100 is provided in a bottom emission mode, the anode electrode 114 can be formed of a transparent conductive material (TCO) such as ITO and IZO, which can transmit light, or a semi-transmissive conductive material such as magnesium (Mg), silver (Ag) or an alloy of magnesium (Mg) and silver (Ag).

Meanwhile, the material constituting the anode electrode 114 can include MoTi. The anode electrode 114 can be a first electrode or a pixel electrode.

The bank 115 is a non-light emission area in which light is not emitted, and can be provided to surround each of light emission areas of the plurality of subpixels SP. That is, the bank 115 can partition (or define) the respective light emission areas EA.

The bank 115 can be formed on the planarization layer 113 to cover an edge of the anode electrode 114, thereby partitioning (or defining) the light emission areas EA (or light emitting portions) of the plurality of subpixels SP.

The bank 115 can be formed to cover an edge of each of the anode electrodes 114 included in each of the sub-pixels SPs and to expose a portion of each of the anode electrodes 114. Accordingly, the bank 115 can cover an end of each of the anode electrodes 114, thereby preventing shorting of the anode electrodes 114 and the cathode electrodes 117. The exposed portion of the anode electrode 114 that is not covered by the bank 115 can be the light emission area EA (or the light emitting portion).

The bank 115 can be formed of an organic layer such as an acrylic resin, an epoxy resin, a phenolic resin, a polyamide resin, and a polyimide resin, but is not limited thereto.

The organic emitting layer 116 is formed on the anode electrode 114 and the bank 115. When a voltage is applied to the anode electrode 114 and the cathode electrode 117, holes and electrons migrate to the organic emitting layer 116, respectively, and they combine with each other in the organic emitting layer 116 to emit light.

The organic light emitting layer 116 can be formed of a plurality of subpixels SP and a common layer provided on the bank 115. In this case, the organic light emitting layer 116 can be provided in a tandem structure in which a plurality of light emitting layers, for example, a yellow-green light emitting layer and a blue light emitting layer are stacked, and can emit white light when an electric field is formed between the anode electrode 114 and the cathode electrode 117.

A color filter 210 suitable for a color of a corresponding subpixel SP can be formed on the second substrate 200. For example, a red color filter can be provided in a red subpixel SP1, a green color filter can be provided in a green subpixel, and a blue color filter can be provided in a blue subpixel. A white subpixel can not include a color filter because the organic light emitting layer 116 emits white light.

The cathode electrode 117 is formed on the organic light emitting layer 116. The cathode electrode 117 can be a common layer commonly formed in the subpixels SP. The cathode electrode 117 can be made of a transparent metal material, a semi-transmissive metal material or a metal material having high reflectance.

When the transparent display apparatus 100 is provided in a top emission mode, the cathode electrode 117 can be formed of a transparent conductive material (TCO) such as ITO and IZO, which can transmit light, or a semi-transmissive conductive material such as magnesium (Mg), silver (Ag) or an alloy of magnesium (Mg) and silver (Ag).

When the transparent display apparatus 100 is provided in a bottom emission mode, the cathode electrode 117 can be formed of a metal material having high reflectance, such as a stacked structure (Ti/Al/Ti) of aluminum and titanium, a stacked structure (ITO/Al/ITO) of aluminum and ITO, an Ag alloy and a stacked structure (ITO/Ag alloy/ITO) of Ag alloy and ITO. The Ag alloy can be an alloy of silver (Ag), palladium (Pd), copper (Cu), etc. The cathode electrode 117 can be a second electrode or an opposing electrode.

The encapsulation layer 118 is formed on the cathode electrode 117. The encapsulation layer 118 serves to prevent oxygen or water from being permeated into the organic light emitting layer 116 and the cathode electrode 117. To this end, the encapsulation layer 118 can include at least one organic layer and at least one inorganic layer.

In the transparent display apparatus 100 according to one embodiment of the present disclosure, the encapsulation layer 118 can be disposed in the non-display area NDA as well as the display area DA. The encapsulation layer 118, according to one example, can be disposed between the cathode electrode 117 (and/or the buffer layer BL) and the second substrate 200.

Since the encapsulation layer 118 is disposed in the display area DA and extends into the non-display area NDA, the encapsulation layer 118 can contact the dam area 120 in the non-display area NDA (or on the periphery) of the display panel. Furthermore, since the transparent display apparatus 100 according to one embodiment of the present disclosure includes the dam area 120 disposed in the display area DA and extending to a portion of the display area DA, the encapsulation layer 118 can be in contact with the dam area 120 (or the connecting member RD included in the dam area 120) even in the display area DA.

Thus, the transparent display apparatus 100 according to one embodiment of the present disclosure can be prevented from moisture permeation toward the display area DA, and even if it is divided into a plurality of pieces through the cutting portion CP, moisture permeation toward the display area DA can be effectively prevented.

Referring again to FIG. 3, the color filter 210 and the black matrix 220 can be disposed between the encapsulation layer 118 and the second substrate 200. In one example, the color filter 210 can be disposed correspondingly to each of a plurality of sub-pixels SPs (or a plurality of light emission areas EA) on the second substrate 200 (or the opposing substrate).

As described above, the white sub-pixel, i.e., the second sub-pixel SP2, can not be provided with a color filter since the organic emitting layer 116 emits white light. On the other hand, the red sub-pixel, i.e., the first sub-pixel SP1, can be provided with the color filter 210 between the encapsulation layer 118 and the second substrate 200.

As shown in FIG. 3, the black matrix 220 can be disposed at the edge of the color filter 210. Thus, the black matrix 220 can prevent color mixing between the sub-pixels SPs. The black matrix 220 can comprise a black-based material and can be disposed in the non-emitting area NEA. In one example, the black matrix 220 can be formed on the second substrate 200 in at least partially overlap the bank 115, thereby reducing the cell gap between the organic emitting layer 116 and the second substrate 200, thereby preventing mixing between sub-pixels.

The transparent display apparatus 100 according to one embodiment of the present disclosure can be provided the plurality of dam areas 120, which is N number (N is an integer greater than one), on the first substrate 110. For example, as shown in FIG. 1, the transparent display apparatus 100 according to one embodiment of the present disclosure can include the first dam area 121 and the second dam area 122. Each of the first dam area 121 and the second dam area 122 can be configured in a closed loop shape (or closed form) enclosing a display area DA of different areas. However, without being limited thereto, each of the first dam area 121 and the second dam area 122 can be configured in a closed loop shape (or closed shape) enclosing a display area DA of the same area as each other.

Referring to FIGS. 1 and 2, the transparent display apparatus 100 according to one embodiment of the present disclosure can further comprise the cutting portion CP provided between the N dam areas 120. The cutting portion CP according to one example can be a portion that is cut by a cutting device such as a laser or a wheel. Thus, when the cutting portion CP is cut by the cutting device, the transparent display apparatus 100 according to one embodiment of the present disclosure can be divided into the first transparent display apparatus 101 and the second transparent display apparatus 102. In FIG. 1, the transparent display apparatus 100 according to one embodiment of the present disclosure is shown configured to be divided into two transparent display apparatuses having different areas (or different horizontal lengths and perpendicular lengths), but is not limited to, it can be configured to be divided into two transparent display apparatuses having the same area (or size).

Referring to FIG. 1 as an example, the transparent display apparatus 100 according to one embodiment of the present disclosure can be configured to be divided into the first transparent display apparatus 101 and the second transparent display apparatus 102. The first transparent display apparatus 101 includes the first area formed by the first cutting portion CP1 and the second transparent display apparatus 102 includes the second area smaller than the first area formed by the second cutting portion CP2. The third transparent display apparatus 103 between the first transparent display apparatus 101 and the second transparent display apparatus 102 does not have the gate driver GD capable of driving the display area DA, and thus cannot be utilized as a transparent display apparatus. However, without being limited thereto, if a gate driver GD can be connected to the third transparent display apparatus 103, the third transparent display apparatus 103 can function as a transparent display apparatus.

On the other hand, when the third transparent display apparatus 103 cannot be utilized as a transparent display apparatus, the filling member RF and the connecting member RD can not be disposed in the area (or the third display area DA3) of the third transparent display apparatus 103 located between the first transparent display apparatus 101 and the second transparent display apparatus 102. Accordingly, the transparent display apparatus 100 according to one embodiment of the present disclosure can have a reduced manufacturing cost since the filling member RF and the connecting member RD are not formed in an area that cannot be utilized as a transparent display apparatus, and the defect rate can be reduced since the area in which the filling member RF and the connecting member RD are not disposed can be cut, and cutting can be facilitated.

As a result, the transparent display apparatus 100 according to one embodiment of the present disclosure can be provided with the plurality of dam areas 120 in a number corresponding to the number of the plurality of gate drivers GDs. Consequently, the transparent display apparatus 100 according to one embodiment of the present disclosure can be provided to be divided into the plurality of transparent display apparatuses as many as the number of the plurality of gate drivers GD (or the number of the plurality of dam areas 120).

Referring again to FIG. 1, in the transparent display apparatus 100 according to one embodiment of the present disclosure, each of the plurality of gate drivers GDs can be disposed in the first direction (Y-axis direction) in the non-display area NDA. Here, the first cutting line CP1a of the first cutting portion CP1 can be configured to be parallel to the direction in which the gate driver GDs are extended to disposed. The second cutting line CP1b of the first cutting portion CP1 is in a direction different from the direction in which the gate driver GD is disposed, for example, it can be configured in the second direction (X-axis direction). However, the second cutting line CP1b can be configured so that it does not contact the gate driver GD. This is because if the second cutting line CP1b is disposed in a direction that intersects the gate driver GD, the gate driver GD can be damaged by the cutting device, and thus cannot be operated as a transparent display apparatus.

Therefore, in the transparent display apparatus 100 according to one embodiment of the present disclosure, the first cutting portion CP1 can be provided on the substrate 110 so that the gate driver GD is not damaged. For example, as shown in FIG. 1, the first cutting portion CP1 can be disposed in the first direction (Y-axis direction) and the second direction (X-axis direction) between the two gate drivers GD1, GD2. Therefore, the transparent display apparatus 100 according to one embodiment of the present disclosure can be cut in the first direction (Y-axis direction) and the second direction (X-axis direction) by the cutting device, thus can be configured to be divided into the first transparent display apparatus 101 and the second transparent display apparatus 102 having different horizontal lengths and perpendicular lengths accordingly. The first transparent display apparatus 101 can include an uncut first gate driver GD1. Also, the second transparent display apparatus 102 can include an uncut second gate driver GD2. However, it is not necessarily limited thereto, and the gate drivers GDs can be cut according to a circuit design change. In this case, the first gate driver GD1 and the first display area DA1 can be provided with the same perpendicular length (or length in the first direction (Y-axis direction)), thus the first transparent display apparatus 101 can be provided compactly. Further, since the second gate driver GD2 and the second display area DA2 can be provided with the same perpendicular length (or length in the first direction (Y-axis direction)), the second transparent display apparatus 102 can be provided compactly.

On the other hand, the second cutting portion CP2 is provided along a portion of the edge of the second dam area 122 surrounding the second display area DA2, and is identical to the first cutting portion CP1 described above except that the horizontal length and the perpendicular length are different from the first cutting portion CP1, so a description thereof will be omitted.

As shown in FIG. 1, the cutting portion CP is configured in a perpendicular direction and a horizontal direction (or a direction in which the perpendicular direction and the horizontal direction are combined), so it can be expressed in terms of a multi-way cutting line. Alternatively, the cutting portion CP is a portion in which the transparent display apparatus 100 is cut in a combined direction of two directions (e.g., a perpendicular direction and a horizontal direction), and thus can be expressed in terms of a two way cutting line.

On the other hand, the transparent display apparatus 100 according to one embodiment of the present disclosure can be provided with only one cutting portion CP, but is not limited thereto, and can be provided with two cutting portions CP, as shown in FIG. 1. For example, the cutting portion CP can include the first cutting portion CP1 and the second cutting portion CP2. The first cutting portion CP1 is disposed between the first transparent display apparatus 101 and the third transparent display apparatus 103, and the second cutting portion CP2 is disposed between the third transparent display apparatus 103 and the second transparent display apparatus 102.

When the cutting device cuts the first cutting portion CP1 and the second cutting portion CP2, the one transparent display apparatus can be divided into three transparent display apparatuses, and the first transparent display apparatus 101 including the first gate driver GD1 and the second transparent display apparatus 102 including the second gate driver GD2 can be utilized as separate transparent display apparatuses having different areas (or transverse lengths and longitudinal lengths). The third transparent display apparatus 103 disposed between the first cutting portion CP1 and the second cutting portion CP2 does not have the gate driver, and therefore cannot function as a transparent display apparatus. However, as described above, if the gate driver can be connected to the third transparent display apparatus 103, it can function as a transparent display apparatus.

Referring to FIG. 1, in the transparent display apparatus 100 according to one embodiment of the present disclosure, the circuit board 160 can include a first circuit board 161, a second circuit board 162, a third circuit board 163, and a fourth circuit board 164. The flexible film 150 can include a plurality of first flexible films 151, a plurality of second flexible films 152, a plurality of third flexible films 153, and a plurality of fourth flexible films 154. For example, the first circuit board 161, and half of the second circuit board 162, can be connected to the first transparent display apparatus 101. The first circuit board 161 can be connected to the first transparent display apparatus 101 via the plurality of first flexible films 151. The second circuit board 162 can be connected to the first transparent display apparatus 101 via the remaining second flexible films 152 of the plurality of second flexible films 152 that are not cut by the first cutting portion CP1. The first circuit board 161, and one half of the second circuit board 162, can be connected to the timing controller via a cable.

The third circuit board 163 can be connected to the third transparent display apparatus 103 via the third flexible film 153. As described above, the third circuit board 163 can not be connected to the timing controller if the third transparent display apparatus 103 fails to function as a transparent display apparatus.

The fourth circuit board 164 can be connected to the second transparent display apparatus 102. For example, the fourth circuit board 164 can be connected to the second transparent display apparatus 102 via the plurality of fourth flexible films 154. The fourth circuit board 164 can be connected to the timing controller via a cable. Thus, when the transparent display apparatus 100 according to one embodiment of the present disclosure is separated (or divided) by the cutting device, the first transparent display apparatus 101 and the second transparent display apparatus 102 can function as respective transparent display apparatuses having different areas (or different horizontal lengths and perpendicular lengths).

Referring to FIG. 3, the transparent display apparatus 100 according to one embodiment of the present disclosure can include the planarization layer 113 disposed on the first substrate 110, and a plurality of inorganic layers 111 disposed between the first substrate 110 and the planarization layer 113. For example, the plurality of inorganic layers 111 can be the gate insulating layer 111a, the interlayer insulating layer 111b, the first passivation layer 111c, and the second passivation layer 111d disposed on the upper surface of the buffer layer BL.

The transparent display apparatus 100, according to one embodiment of the present disclosure, can include an undercut portion UC from which the planarization layer 113 and the plurality of inorganic layers 111 have been partially removed.

The undercut portion UC according to one example can be formed by partially removing each of the interlayer insulating layer 111b, the first passivation layer 111c, and the second passivation layer 111d. As shown in FIG. 3, the undercut portion UC can be formed in the transmissive portion TA, that is, the transmissive portion TA can include the undercut portion UC.

The undercut portion UC is for disconnecting the organic emitting layer 116 provided in the transmissive portion TA. Since in the transparent display apparatus 100 according to one embodiment of the present disclosure, the organic emitting layer 116, the cathode electrode 117, and the encapsulation layer 118 is formed after the undercut portion UC is formed, the organic emitting layer 116 (or the organic emitting layer 116, the cathode electrode 117, and the encapsulation layer 118) can be disconnected by the undercut portion UC. Thus, the transparent display apparatus 100 according to one embodiment of the present disclosure can be prevented from moisture permeation through the organic emitting layer 116.

The undercut portion UC according to one example can be provided in the transmissive portion TA in a plurality. Since the undercut portion UC is an area in which the organic emitting layer 116 is disconnected, moisture permeation to the display area DA can be prevented even when the undercut portion UC is cut by the cutting device. Therefore, in the transparent display apparatus 100 according to one embodiment of the present disclosure, the cutting portion CP can be any one of the plurality of undercut portions UC. For example, as shown in FIG. 3, the undercut portions UC can be disposed along an edge of each of the plurality of moisture permeable bypass portions 130 disposed in the transmissive portion TA. Since each of the plurality of moisture permeable bypass portions 130 is disposed in the form of an island spaced apart from the planarization layer 113 disposed in the light emission area EA, it can be expressed in terms of an island OC or first planarization layer. In contrast, the planarization layer 113 disposed to overlap the light emission area EA (and/or the non-emission area NEA) is disposed to cover the thin film transistor 112, and thus can be expressed in terms of a capping OC or second planarization layer.

For example, as shown in FIG. 2, the transmissive portion TA can have two moisture permeable bypass portions (or first planarization layers 130) extended in the first direction (Y-axis direction), and can be disposed in parallel. In this case, four undercut portions UC can be disposed in one transmissive portion TA, as shown in FIG. 3. Any one of these four undercut portions UC can be the cutting portion CP. However, it is not necessarily limited thereto, and the cutting portion CP can be disposed (or formed) in the transmissive portion TA and/or the light emission area EA rather than in the undercut portion UC. Further, the cutting portion CP can be disposed in an area other than the dam area 120, and can not be disposed in an area where the filling member RF is disposed. This is because, if the cutting portion CP is disposed in the area where the filling member RF is disposed, moisture permeation can occur through the organic layer such as the organic emitting layer when it is cut by the cutting device. Therefore, in the transparent display apparatus 100 according to one embodiment of the present disclosure, the cutting portion CP can be disposed in at least one of the undercut portion UC in an area where the filling member RF is not disposed, the light emission area EA in an area where the filling member RF is not disposed, and the transmissive portion TA in an area where the filling member RF is not disposed. Hereinafter, it will be described by way of example that the undercut portion UC is the cutting portion CP.

The transparent display apparatus 100 according to one embodiment of the present disclosure can be provided as the plurality of transparent display apparatuses having different areas or the same area when any one of the plurality of undercut portions UC is cut by the cutting device. As shown in FIG. 3, since the organic emitting layer 116 is disconnected in the undercut portion UC, moisture permeation through the organic emitting layer 116 can be prevented even when it is cut by the cutting device. Further, since the cutting portion CP is disposed between the plurality of dam areas 120, even when cut by the cutting device, the edges of each transparent display apparatus (e.g., the first transparent display apparatus 101 and the second transparent display apparatus 102) can be provided with a structure in which the dam areas 120 surround the display area DA. Also, since in each of the transparent display apparatuses (e.g., the first transparent display apparatus 101 and the second transparent display apparatus 102) the getters included in the connecting members RD disposed at the edges can be capable of absorbing moisture and oxygen, the prevention of moisture permeation to the display area DA can be further maximized.

Referring to FIG. 3, in the transparent display apparatus 100 according to one embodiment of the present disclosure, the organic emitting layer 116 can be disconnected at the undercut portion UC. In addition, the cathode electrode 117 and the encapsulation layer 118 can also be disconnected at the undercut portion UC. Thus, as shown in FIG. 3, the moisture permeable bypass portion 130, the organic emitting layer 116 disposed on the moisture permeable bypass portion 130, the cathode electrode 117, and the encapsulation layer 118 can be disposed in an island shape. Thus, the connection member RD can be disposed up to the undercut portion UC in both sides of the moisture permeable bypass portion 130. In the transparent display apparatus 100 according to one embodiment of the present disclosure, the connection member RD including the getter is disposed up to the undercut portion UC, thus moisture permeation can be further prevented. However, it is not necessarily limited thereto, and the connecting member RD can be partially formed only on one side of the moisture permeable bypass portion 130.

On the other hand, the transparent display apparatus 100 according to one embodiment of the present disclosure can be configured that various types (or various sizes) of the transparent display device can be manufactured without an additional masking process through the process of forming the undercut portion UC that disconnects the organic emitting layer 116, thus production energy can be reduced compared to the case of manufacturing various types (or various sizes) of the transparent display device through various processes.

As described above, in the transparent display apparatus 100 according to one embodiment of the present disclosure, the undercut portions UC are disposed along an edge of each of the plurality of moisture permeable bypass portions 130, thus each of the plurality of moisture permeable bypass portions 130 can have an island shape by the undercut portions UC. Therefore, as shown in FIG. 2, each of the plurality of moisture permeable bypass portions 130 can be configured in an island shape and spaced apart from each other. In the transparent display apparatus 100 according to one embodiment of the present disclosure, the plurality of moisture permeable bypass portions 130 is spaced apart from each other, thereby preventing from being permeated through the moisture permeable bypass portions 130, which are provided with the same material (e.g., organic material) as the planarization layer 113.

Furthermore, in the transparent display apparatus 100 according to one embodiment of the present disclosure, each of the plurality of moisture permeable bypass portions 130 is disposed to overlap in at least one of the first direction (Y-axis direction) and the second direction (X-axis direction) different from the first direction (Y-axis direction), a moisture permeable path through the disconnected organic emitting layer 116′ (shown in FIG. 3) between the plurality of moisture permeable bypass portions 130, can be lengthened. That is, each of the plurality of moisture permeable bypass portions 130 can be provided with a double T structure, thereby lengthening the moisture permeation path through the disconnected organic emitting layer 116′. Accordingly, the plurality of moisture permeable bypass portions 130 can be expressed by terms such as moisture permeable delay portion, moisture permeable path delay portion, moisture permeable barrier portion, and moisture permeable path barrier portion.

For example, in the first transparent display apparatus 101 cut by the first cutting portion CP1, moisture and oxygen from the outside can be permeated through between the plurality of first moisture permeable bypass portions 131 in the first display area DA1, the plurality of first moisture permeable bypass portions 131 are disposed in a diagonal form (or diagonal form) or a zigzag form, as shown in FIG. 4, thus a moisture permeable path PP (or a first moisture permeable path PP1) can be lengthened.

As shown in FIG. 4, moisture and/or oxygen permeated to the lower of the first display area DA1 can be permeated along a moisture permeation path, which is a path along the gap between the plurality of first moisture permeable bypass portions 131 to the upper left. For example, the moisture permeation path can comprise a combination of a leftward direction D1, an upward direction D2, and a downward direction D3. Since each of the plurality of first moisture permeable bypass portions 131 is configured as a double-T structure, the moisture and/or oxygen that is moved to the upper left side is bound to be moved not only in the leftward direction D1 and the upward direction D2, but also in the downward direction D3, which is a reverse direction to the upward direction D2, thereby lengthening the moisture permeation path. Accordingly, the first transparent display apparatus 101 formed by cutting along the first cutting portion CP1 can have the moisture permeable path lengthened due to the plurality of moisture permeable bypass portions 130 (or the plurality of first moisture permeable bypass portions 131) provided in the first display area DA1, and thus, its reliability and service life can be increased compared to a conventional transparent display apparatus without the plurality of moisture permeable bypass portions 130.

On the other hand, as shown in FIG. 5, one example of the transparent display apparatus according to the comparative example is provided with a structure in which the planarization layers PL in the transmissive portion TA are connected to each other to prevent moisture permeation through the disconnected organic emitting layer 116′. Thus, as shown in FIG. 5, the disconnected organic emitting layer 116′ is provided in an island shape. Therefore, an example of the transparent display apparatus according to the comparative example can prevent moisture permeation through the disconnected organic emitting layer 116′. However, an example of the transparent display apparatus according to the comparative example is provided with a structure in which the planarization layers PL made of organic material are connected to each other, thus moisture permeation through the planarization layers PL cannot be prevented. As a result, the transparent display device according to the comparative example shown in FIG. 5 can suffer from a decrease in reliability due to moisture permeation through the planarization layer PL, which can result in a decrease in service life.

As shown in FIG. 6, another example of the transparent display apparatus according to the comparative example is provided with a structure in which the planarization layer PL is disconnected in both the first direction (Y-axis direction) and the second direction (X-axis direction) to prevent moisture permeation through the planarization layer PL. Thus, as shown in FIG. 6, the planarization layer PL can be provided in a plurality, and the plurality of planarization layers PL can be provided in straight line island shapes. Thus, in another example of the transparent display apparatus according to the comparative example, moisture permeation through the planarization layer PL can be prevented. However, another example of the transparent display apparatus according to the comparative example is provided with a structure in which the organic emitting layers 116′ between the plurality of planarization layers PL are connected to each other, thus moisture permeation through the organic emitting layers 116′ cannot be prevented. As a result, the transparent display apparatus according to a comparative example such as FIG. 6 can suffer from a decrease in reliability due to moisture permeation through the organic emitting layer 116′ between the plurality of planarization layers PLs, which can result in a decrease in service life.

In contrast, in the transparent display apparatus 100 according to one embodiment of the present disclosure, each of the plurality of moisture permeable bypass portions 130 is configured in a double T shape rather than a straight shape, and the plurality of moisture permeable bypass portions 130 are disposed to overlap in at least one of the first direction (Y-axis direction) and the second direction (X-axis direction) different from the first direction (Y-axis direction). Thus, moisture permeation through each of the plurality of moisture permeable bypass portions 130 can be prevented, and the path of moisture permeation through the organic emitting layer 116′ (shown in FIG. 3), between the plurality of moisture permeable bypass portions 130 can be lengthened, thereby increasing reliability and service life.

In the transparent display apparatus 100 according to one embodiment of the present disclosure, each of the plurality of moisture permeable bypass portions 130 can include the plurality of first moisture permeable bypass portions 131 in the first display area DA1, a plurality of second moisture permeable bypass portions 132 in the second display area DA2, and a plurality of third moisture permeable bypass portions 133 in the third display area DA3.

Referring to FIG. 2, the plurality of first moisture permeable bypass portions 131, according to one example can include a bypass member 1311. The bypass member 1311 can include a first bypass member 1311a, a second bypass member 1311b, a third bypass member 1311c, and a fourth bypass member 1311d. The first bypass member 1311a is disposed in the first direction (Y-axis direction), the second bypass member 1311b is spaced apart from the first bypass member 1311a and disposed in parallel to the first bypass member 1311a, and the third bypass member 1311c is disposed in the second direction (X-axis direction) different from the first direction (Y-axis direction) and connecting the first bypass member 1311a and the second bypass member 1311b, and the fourth bypass member 1311d is disposed at one end of the first bypass member 1311a (e.g., a upper end of the first bypass member 1311a) and in parallel to the third bypass member 1311c. Here, the third bypass member 1311c can be connected a point between two ends of the first bypass member 1311a and a point between two ends of the second bypass member 1311b. Further, the first bypass member 1311a can be connected to a point between two ends of the fourth bypass member 1311d. Thus, each of the plurality of first moisture permeable bypass portions 131 can be configured in a double-T configuration. Since each of the plurality of first moisture permeable bypass portions 131, as shown in FIG. 2, includes the fourth bypass member 1311d disposed in the second direction (X-axis direction) at an upper end of the first bypass member 1311a disposed in the first direction (Y-axis direction), it can be expressed in terms of a left moisture permeable bypass portion having a left double-T shape.

On the other hand, the first bypass member 1311a and the second bypass member 1311b can be disposed to extend in the first direction (Y-axis direction) in the transmissive portions TA of different pixels. Furthermore, each of the first bypass member 1311a and the second bypass member 1311b can be connected as one without being disconnected at the transmissive portions TA of each of the pixels adjacent to upper and lower. Each of the third bypass member 1311c and the fourth bypass member 1311d can be disposed to extend in the second direction (X-axis direction) between the upper and lower adjacent pixels.

Accordingly, in the transparent display apparatus 100 according to one embodiment of the present disclosure, each of the plurality of first moisture permeable bypass portions 131 having a left double T shape are spaced apart from each other, and overlaps in at least one of the first direction (Y-axis direction) and the second direction (X-axis direction), therefore moisture permeation in the upper left direction can be delayed, as shown in FIG. 4. The first permeation path PP1 can include the bypass members disposed in different directions, for example, at the portion where the first bypass member 1311a and the third bypass member 1311c are connected, the moisture permeation path is inevitably formed in the downward direction D3, thereby extending the moisture permeation path. As a result, in the first transparent display apparatus 101, which can be formed by cutting along the first cutting portion CP1, moisture permeation can be delayed due to the plurality of first moisture permeable bypass portions 131 disposed in the first display area DA1, thereby increasing its reliability and service life.

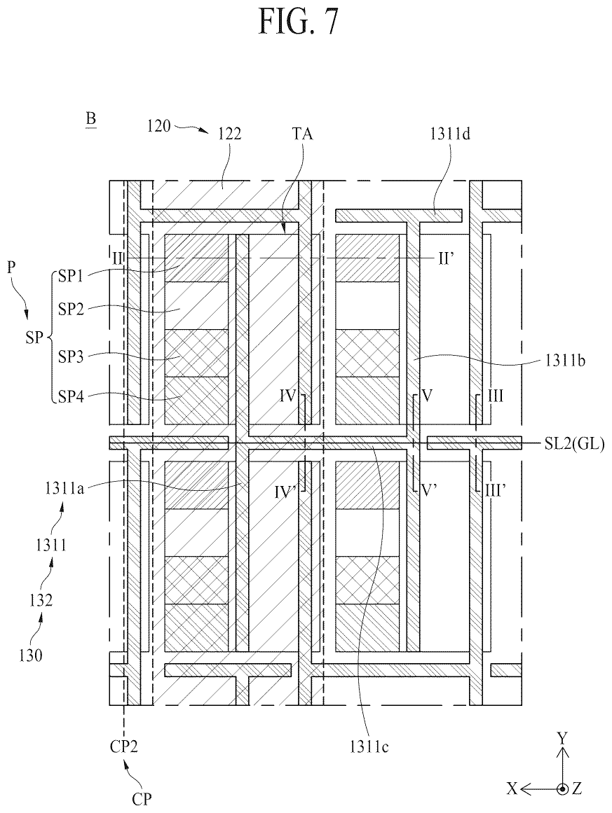

Hereinafter, with reference to FIGS. 7 to 9, a second transparent display apparatus 102 that can be cut by the second cutting portion CP2 will be described in detail.

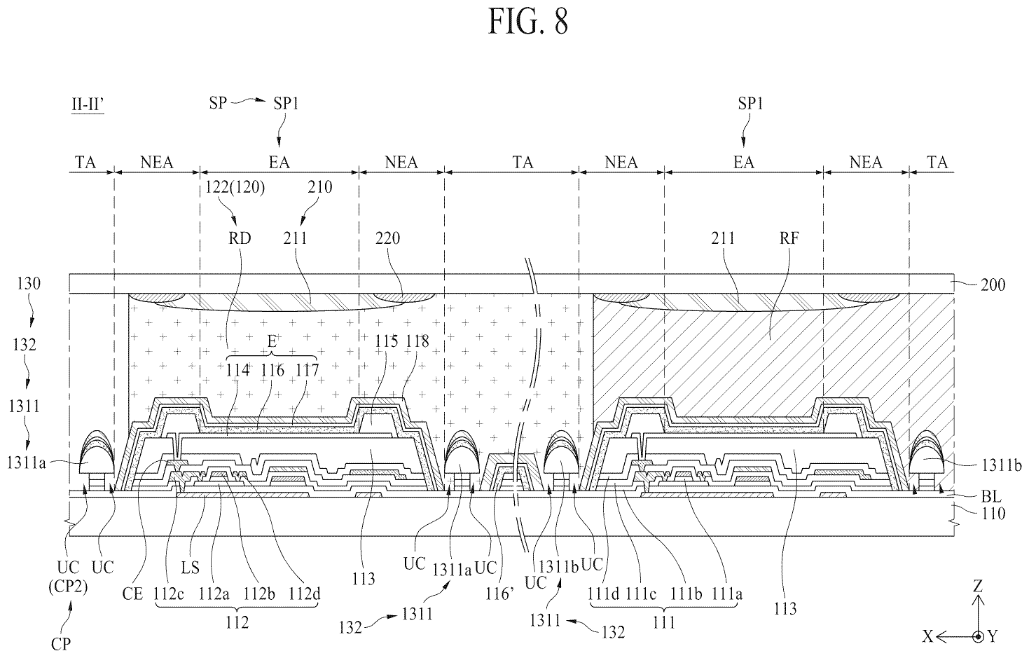

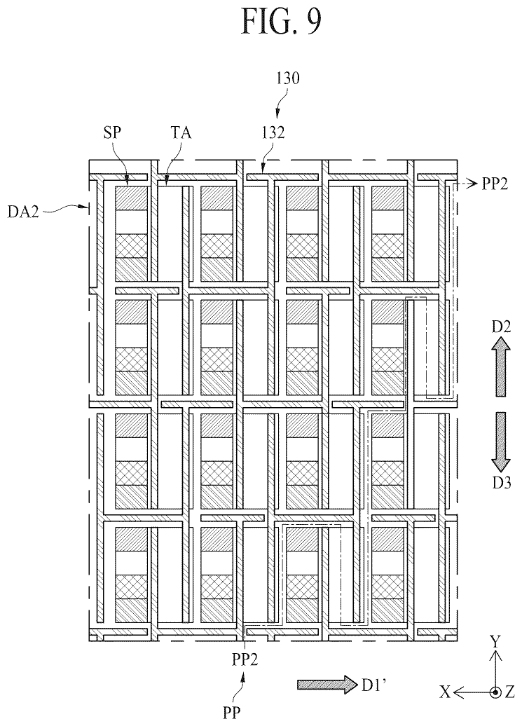

FIG. 7 is an enlarged top view of portion B shown in FIG. 1, FIG. 8 is a schematic cross-sectional view cut along line II-II′ shown in FIG. 7, and FIG. 9 is an enlarged top view of a portion of the second display area in portion B shown in FIG. 1.

The second transparent display apparatus 102 can include the second display area DA2. The second display area DA2 can include the plurality of second moisture permeable bypass portions 132, as shown in FIG. 7. Each of the plurality of second moisture permeable bypass portions 132 can be provided in an island shape, thus they are spaced apart from each other. For example, each of the plurality of second moisture permeable bypass portions 132 can be provided as a combination of a “T” and a left lying “T”. Each of the plurality of second moisture permeable bypass portions 132 can have a combination of two “T”s, and thus can be expressed in terms of a double “T”.

The transparent display apparatus 100 according to one embodiment of the present disclosure has the plurality of second moisture permeable bypass portions 132 spaced apart from each other, thus moisture and oxygen from the outside can be prevented from permeating through the second moisture permeable bypass portions 132. Further, as shown in FIG. 7, in the transparent display apparatus 100 according to one embodiment of the present disclosure, the plurality of second moisture permeable bypass portions 132 is spaced apart from each other, and overlaps in at least one of the first direction (Y-axis direction) and the second direction (X-axis direction) different from the first direction (Y-axis direction). Therefore, a path for external moisture and oxygen to be permeated through the organic layer (e.g., the organic emitting layer 116) between each of the plurality of second moisture permeable bypass portions 132 can be lengthened. Thus, in the transparent display apparatus 100 according to one embodiment of the present disclosure, due to the plurality of moisture permeable bypass portions 130 moisture, permeation can be prevented or the path of moisture permeation can be lengthened, thereby improving reliability.

Each of the plurality of second moisture permeable bypass portions 132 is formed in the second display area DA2 and has the same operative effect as each of the plurality of first moisture permeable bypass portions 131, except that it is configured in a different form than each of the plurality of first moisture permeable bypass portions 131 described above. Accordingly, identical configurations have been given identical drawing symbols so that the different configurations will be focused and described hereinafter.

Referring now to FIGS. 7 to 9, the plurality of second moisture permeable bypass portions 132 according to one example can include the bypass member 1311. The bypass members 1311 can include the first bypass member 1311a disposed in the first direction (y-axis direction), the second bypass member 1311b spaced apart from the first bypass member 1311a and disposed in parallel to first bypass member 1311a, and the third bypass member 1311c disposed in the second direction (x-axis direction) different from the first direction (y-axis direction) and connecting the first bypass member 1311a and the second bypass member 1311b, and the fourth bypass member 1311d disposed at one end of the second bypass member 1311b (e.g., an upper end of the second bypass member 1311b) and in parallel to the third bypass member 1311c. Here, the third bypass member 1311c can be connected a point between two ends of the first bypass member 1311a and a point between two ends of the second bypass member 1311b. Further, the second bypass member 1311b can be connected to a point between two ends of the fourth bypass member 1311d. Thus, each of the plurality of second moisture permeable bypass portions 132 can be provided in a double-T configuration. Since each of the plurality of second moisture permeable bypass portions 132, as shown in FIG. 7, includes the fourth bypass member 1311d disposed in the second direction (X-axis direction) at an upper end of the second bypass member 1311b disposed in the first direction (Y-axis direction), it can be expressed in terms of a right moisture permeable bypass portion having a right double-T shape.

On the other hand, the first bypass member 1311a and the second bypass member 1311b can be disposed to extend in the first direction (Y-axis direction) in the transmissive portions TA of different pixels. Furthermore, each of the first bypass member 1311a and the second bypass member 1311b can be connected as one without being disconnected at the transmissive portions TA of each of the pixels adjacent to upper and lower. Each of the third bypass member 1311c and the fourth bypass member 1311d can be disposed to extend in the second direction (X-axis direction) between the upper and lower adjacent pixels.

Accordingly, in the transparent display apparatus 100 according to one embodiment of the present disclosure, each of the plurality of second moisture permeable bypass portions 132 having the right double T shape are spaced apart from each other, and overlaps in at least one of the first direction (Y-axis direction) and the second direction (X-axis direction), therefore moisture permeation in the upper right direction can be delayed, as shown in FIG. 9. The second permeation path PP2 can include the bypass members disposed in different directions, for example, at the portion where the second bypass member 1311b and the third bypass member 1311c are connected, a moisture permeation path is inevitably formed in the downward direction D3, thereby extending the moisture permeation path. For example, the second moisture permeation path can be formed as a combination of the rightward direction D1′, the upward direction D2, and the downward direction D3. As a result, in the second transparent display apparatus 102, which can be formed by cutting along the second cutting portion CP2, moisture permeation can be delayed due to the plurality of second moisture permeable bypass portions 132 disposed in the second display area DA2, thereby increasing reliability and service life.

On the other hand, since the second display area DA2 is surrounded by the second dam area 122, the second cutting portion CP2 can be disposed adjacent to the second dam area 122, as shown in FIG. 8.

Referring now to FIGS. 2 and 7, in the transparent display apparatus 100 according to one embodiment of the present disclosure, the second moisture permeable bypass portion 132 can be provided to have a symmetrical shape with the first moisture permeable bypass portion 131. For example, the second moisture permeable bypass portion 132 can have a symmetrical shape with the first moisture permeable bypass portion 131 with respect to the reference line AL. Accordingly, the second moisture permeable bypass portion 132 can be expressed in terms of the right moisture permeable bypass portion, and the first moisture permeable bypass portion 131 can be expressed in terms of the left moisture permeable bypass portion.

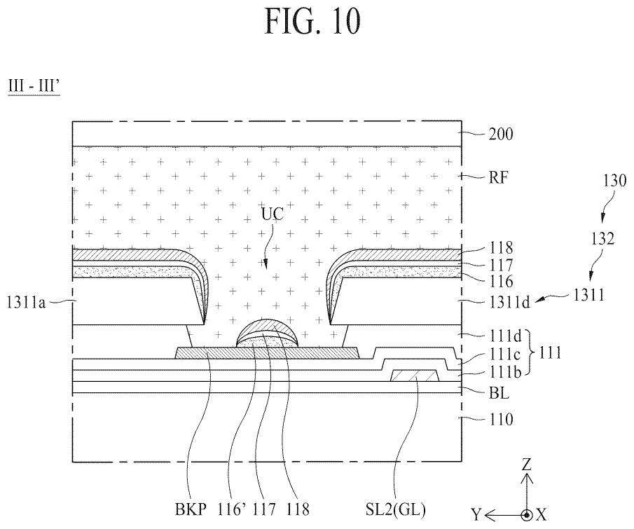

FIG. 10 is a schematic cross-sectional view cut along line III-III′ shown in FIG. 7.

Referring to FIG. 10, in the transparent display apparatus 100 according to one embodiment of the present disclosure, the undercut portion UC can include a blocking portion BKP disposed on at least one inorganic layer covering the gate line GL. In one example, the blocking portion BKP can partially overlap the moisture permeable bypass portion 130 (or the fourth bypass member 1311d) between the first passivation layer 111c and the second passivation layer 111d. The blocking portion BKP, as shown in FIG. 7 can be formed at a portion where the moisture permeable bypass portion 130 and the second line SL2 (or gate line GL) overlap.

The blocking portion BKP is to prevent all inorganic layers disposed on the upper part of the wiring (e.g., the second line SL2 (or the gate line GL)) from being etched by the etchant used when the undercut portion UC is formed. Accordingly, as shown in FIG. 10, the blocking portion BKP is disposed on the inorganic layer (or the interlayer insulating layer 111b and the first passivation layer 111c) on the second line SL2 (or the gate line GL), thus the inorganic layer (or the interlayer insulating layer 111b and the first passivation layer 111c) can be protected from the etching solution. Accordingly, contact between the second line SL2 (or gate line GL) and the cathode electrode 117 can be prevented when the cathode electrode 117 is deposited. The blocking portion BKP according to one example can include a metallic material having high resistance to the etchant. The blocking portion BKP can be formed in the same layer as the connection electrode CE (shown in FIG. 8).

Referring to FIG. 10, the blocking portion BKP can be provided to have a wider width than the undercut portion UC in the first direction (Y-axis direction). Accordingly, an edge of the blocking portion BKP can be covered by the second passivation layer 111d. On the other hand, as shown in FIG. 10, each of the first bypass member 1311a and the fourth bypass member 1311d can be provided with a structure protruding toward the center of the undercut portion UC. Accordingly, each of the first bypass member 1311a and the fourth bypass member 1311d can partially overlap the blocking portion BKP. Due to the protruding structure of each of the first bypass member 1311a and the fourth bypass member 1311d, the organic emitting layer 116 can be disconnected in the undercut portion UC.

The organic emitting layer 116′ disconnected by the undercut portion UC can be in contact with the upper surface of the blocking portion BKP. Each of the cathode electrode 117 and the encapsulation layer 118 disposed on the disconnected organic emitting layer 116′ can be in contact with the upper surface of the blocking portion BKP, but is not necessarily limited thereto.

On the other hand, as shown in FIG. 10, on the upper side of the encapsulation layer 118 and the blocking portion BKP, the filling member RF used for bonding the first substrate 110 and the second substrate 200 can be disposed.

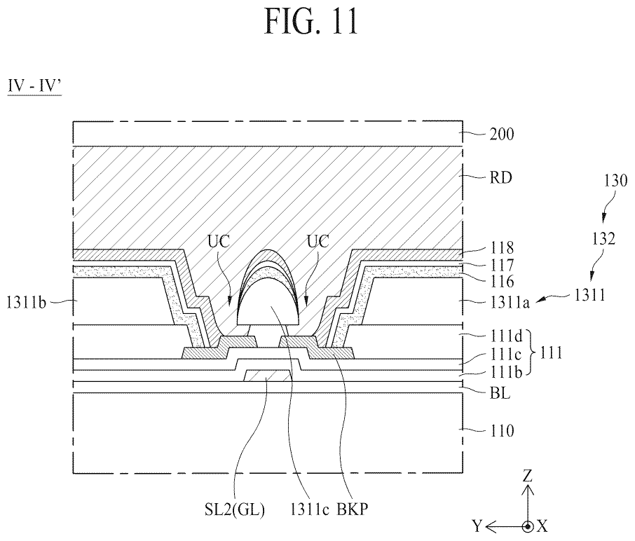

FIG. 11 is a schematic cross-sectional view cut along line IV-IV′ shown in FIG. 7.

Referring to FIG. 11, the blocking portion BKP can partially overlap the gate line GL. As shown in FIG. 11, the blocking portion BKP according to an example can be formed between the second bypass member 1311b and the third bypass member 1311c, and between the third bypass member 1311c and the first bypass member 1311a, respectively. Thus, the blocking portion BKP can partially overlap the gate line GL. As the blocking portion BKP is configured to partially overlap the gate line GL, the plurality of inorganic layers (e.g., the interlayer insulating layer 111b and the first passivation layer 111c) on the gate line GL can be protected from the etchant. Thus, contact of the second line SL2 (or gate line GL) with the cathode electrode 117 during deposition of the cathode electrode 117 can be prevented.

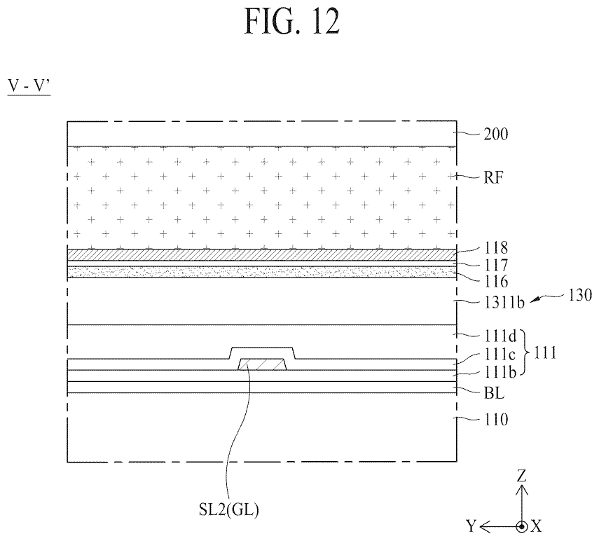

FIG. 12 is a schematic cross-sectional view cut along line V-V′ shown in FIG. 7.

Referring to FIG. 12, the second line SL2 (or gate line GL) can be configured to partially overlap the second bypass member 1311b. In the case of FIG. 12, since the plurality of inorganic layers 111 on the second line SL2 (or gate line GL) have a non-etched structure, the blocking portion BKP can not be provided on the second line SL2 (or gate line GL) and/or on some inorganic layers of the plurality of inorganic layers.

As a result, the transparent display apparatus 100 according to one embodiment of the present disclosure is provided with the blocking portion BKP on the second line SL2 (or gate line GL) passing through the portion where the undercut portion UC is formed, the inorganic film layer (or the inorganic film layer on a predetermined area including the second line SL2 (or gate line GL)) on the second line SL2 (or gate line GL) can be protected from the etching solution, thus contact between the cathode electrode 117 and the second line SL2 (or gate line GL) can be prevented.

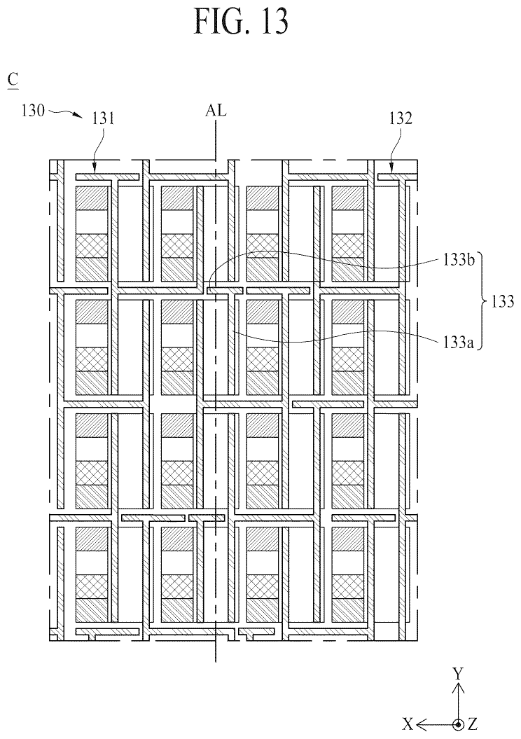

FIG. 13 is an enlarged top view of C portion shown in FIG. 1.

Referring to FIG. 13, the third display area DA3, which partially overlaps the reference line AL, can include the plurality of third moisture permeable bypass portions 133. As described above, the first moisture permeable bypass portion 131 and the second moisture permeable bypass portion 132 can have a symmetrical shape with respect to the reference line AL. For example, the first moisture permeable bypass portion 131 can be configured in a double T shape, which can be expressed in terms of a left moisture permeable bypass portion, and the second moisture permeable bypass portion 132 can be configured in a double T shape, which can be expressed in terms of a right moisture permeable bypass portion. Thus, a space without the moisture permeable bypass portion can occur in a portion adjacent to the first moisture permeable bypass portion 131 and the second moisture permeable bypass portion 132, and the third moisture permeable bypass portion 133 is to fill this space.

As shown in FIG. 13, the third moisture permeable bypass portion 133 can be configured to have a different shape from the first moisture permeable bypass portion 131 and the second moisture permeable bypass portion 132. For example, the third moisture permeable bypass portion 133 can include the first bypass member 133a disposed in the first direction (Y-axis direction) and the second bypass member 133b connected to a first end (or an upper end) of the first bypass member 133a and disposed in the second direction (X-axis direction).

The first bypass member 133a can be connected to a point between two ends of the second bypass member 133b. Accordingly, the plurality of third moisture permeable bypass portions 133 can be configured to fill the space between the plurality of first moisture permeable bypass portions 131 and the plurality of second moisture permeable bypass portions 132, moisture permeation can be delayed by lengthening the permeation path of moisture and/or oxygen that penetrates and moves between the plurality of first moisture permeable bypass portions 131 to delay moisture permeation. Further, the plurality of third moisture permeable bypass portions 133 can delay moisture permeation by lengthening the permeation path of moisture and/or oxygen that penetrates and moves between the plurality of second moisture permeable bypass portions 132. For example, the third moisture permeable bypass portion 133 can be configured in a T-shape in which the first bypass member 133a is coupled to a portion spaced to the right from the center of the second bypass member 133b, or the first bypass member 133a can be configured in a T-shape in which the first bypass member 133a is coupled to a portion spaced to the left from the center of the second bypass member 133b.

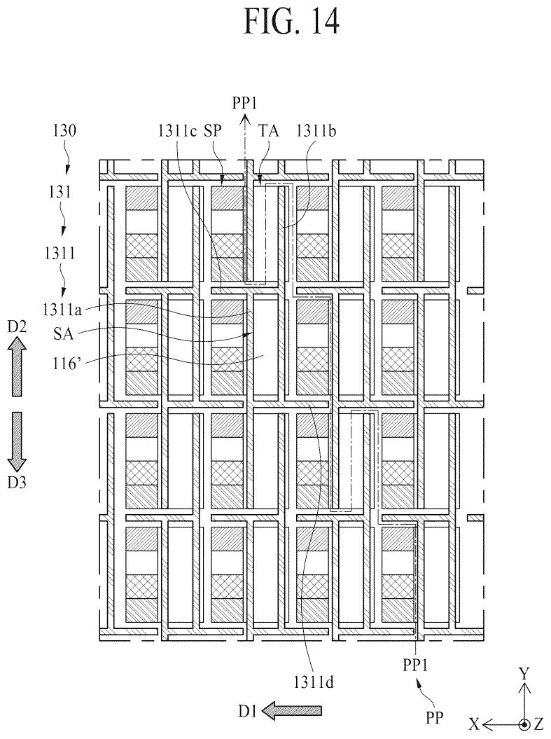

FIG. 14 is a schematic top view of a transparent display device according to a second embodiment of the present disclosure.

Referring now to FIG. 14, the transparent display apparatus 100 according to the second embodiment of the present disclosure is identical to the transparent display device according to FIG. 1 described above, except that the structure of the plurality of moisture permeable bypass portions 130 (or the plurality of first moisture permeable bypass portions 131) has been changed. Accordingly, the same drawing symbols have been assigned to the same configurations, so that elements with different configurations will be focused and described hereinafter.

In the case of the transparent display device according to FIG. 1 above, each of the plurality of moisture permeable bypass portions 130 is configured in a double T shape. For example, the first moisture permeable bypass portion 131 disposed in the first display area DA1 can be configured in the left double T shape. Thus, the transparent display device according to FIG. 1 can have a feature in which moisture permeation to the left upper direction in the first display area DA1 can be prevented more effectively than moisture permeation to the right upper direction.

In contrast, in the case of the transparent display device according to FIG. 14, each of the plurality of moisture permeable bypass portions 130 is configured in the form of a vortex. For example, the first moisture permeable bypass portion 131 disposed in the first display area DA1 includes the first bypass member 1311a, the second bypass member 1311b, the third bypass member 1311c, and the fourth bypass member 1311d. The first bypass member 1311a is disposed in parallel to the first direction (Y-axis direction), and the second bypass member 1311b is disposed in parallel to the first bypass member 1311a and spaced apart from the first bypass member 1311a, the third bypass member 1311c is disposed in the second direction (X-axis direction) different from the first direction (Y-axis direction) and connecting the first bypass member 1311a and the second bypass member 1311b, and the fourth bypass member 1311d is spaced apart from the third bypass member 1311c and disposed in parallel to the third bypass member 1311c and connecting the first bypass member 1311a and the second bypass member 1311b. Here, the third bypass member 1311c can connect one end (or an upper end) of the first bypass member 1311a and a point between two ends of the second bypass member 1311b, and the fourth bypass member 1311d can connect one end (or lower end) of the second bypass member 1311b and a point between two ends of the first bypass member 1311a. Thus, in the case of the transparent display device according to FIG. 14, each of the plurality of moisture permeable bypass portions 130 can be configured in the form of a vortex.

On the other hand, the first bypass member 1311a and the second bypass member 1311b can be disposed to extend in the first direction (Y-axis direction) from the transmissive portions TA of different pixels. Further, each of the first bypass member 1311a and the second bypass member 1311b can be connected as one without being disconnected at the transmissive portions TA of each of the pixels that are adjacent to upper and lower. As shown in FIG. 14, the first bypass member 1311a and the second bypass member 1311b can only partially overlap in the second direction (X-axis direction). Each of the third bypass member 1311c and the fourth bypass member 1311d can be disposed to extend in the second direction (x-axis direction) between upper and lower adjacent pixels. As shown in FIG. 14, the third bypass member 1311c and the fourth bypass member 1311d can only partially overlap in the first direction (Y-axis direction).

The transparent display apparatus 100 according to the second embodiment of the present disclosure can further include a sealed area SA in which each of the plurality of moisture permeable bypass portions 130 is surrounded by a portion of each of the first bypass member 1311a, the second bypass member 1311b, the third bypass member 1311c, and the fourth bypass member 1311d. As shown in FIG. 14, the sealed area SA according to one example can be partially disposed in the transmissive portion TA. Thus, the organic emitting layer 116′ disposed in the sealed area SA is surrounded by the plurality of moisture permeable bypass portions 130 (or first to fourth bypass members 1311a, 1311b, 1311c, 1311d), and thus can not be utilized as a moisture permeation path.

Furthermore, in the transparent display apparatus 100 according to the second embodiment of the present disclosure, each of the plurality of moisture permeable bypass portions 130 is configured in the form of a vortex, thus the moisture permeable path PP (or the first moisture permeable path PP1) includes a path in the downward direction D3 as shown in FIG. 14, thereby extending the moisture permeable path. Thus, the transparent display apparatus 100 according to the second embodiment of the present description can have a feature in which moisture permeation to the left upper direction can be prevented more effectively than moisture permeation to the right upper direction.

As a result, the transparent display apparatus 100 according to the second embodiment of the present disclosure can have each of the plurality of moisture permeable bypass portions 130 in the form of a vortex, thus the moisture permeation path can be blocked by the sealed area SA, and the moisture permeation path can be lengthened by the first to fourth bypass members 1311a, 1311b, 1311c, 1311d, thereby delaying the permeation of moisture and oxygen. Thus, the transparent display apparatus 100 according to the second embodiment of the present disclosure can have an improved service life due to improved reliability against moisture permeation.

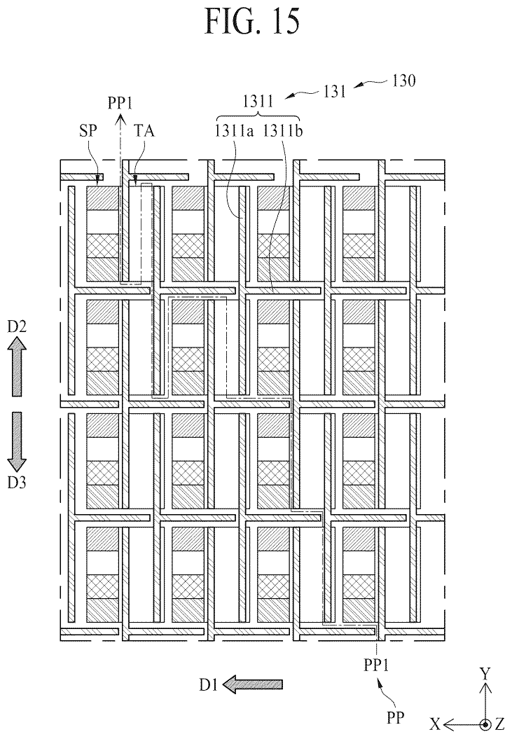

FIG. 15 is a schematic top view of a transparent display device according to a third embodiment of the present disclosure.

Referring now to FIG. 15, the transparent display apparatus 100 according to the third embodiment of the present disclosure is identical to the transparent display device according to FIG. 1 described above, except that the structure of the plurality of moisture permeable bypass portions 130 (or the plurality of first moisture permeable bypass portions 131) has been changed. Accordingly, the same drawing symbols have been assigned to the same configurations, so that elements with different configurations will be focused and described hereinafter.

In the case of the transparent display device according to FIG. 1 above, each of the plurality of moisture permeable bypass portions 130 is configured in a double-T shape. For example, the first moisture permeable bypass portion 131 disposed in the first display area DA1 can be configured in a left double-T shape. Thus, the transparent display device according to FIG. 1 can have a feature in which moisture permeation to the left upper direction in the first display area DA1 can be prevented more effectively than moisture permeation to the right upper direction.

In contrast, in the case of the transparent display device according to FIG. 15, each of the plurality of moisture permeable bypass portions 130 is provided in the left lying “T”. For example, the first moisture permeable bypass portion 131 disposed in the first display area DA1 can include the first bypass member 1311a and the second bypass member 1311b. The first bypass member 1311a is disposed in the first direction (Y-axis direction), and the second bypass member 1311b is disposed in the second direction (X-axis direction) different from the first direction (Y-axis direction) and connected between two ends of the first bypass member 1311a. Thus, in the case of the transparent display apparatus according to FIG. 15, each of the plurality of moisture permeable bypass portions 130 can be configured in the left lying “T”.

On the other hand, the first bypass member 1311a can be extended in the first direction (Y-axis direction) in the transmissive portions TA of different pixels. Further, the first bypass member 1311a can be connected as one without being disconnected at the transmissive portions TA of each of the pixels adjacent to upper and lower. The second bypass member 1311b can be disposed to extend in the second direction (X-axis direction) between the upper and lower adjacent pixels.

Accordingly, the transparent display apparatus 100 according to the third embodiment of the present disclosure can have each of the plurality of moisture permeable bypass portions 130 in the form of the left lying “T”, thus the moisture permeable path PP (or the first moisture permeable path PP1) includes a path in the downward direction D3 as shown in FIG. 15, thereby extending the moisture permeable path.

As a result, in the transparent display apparatus 100 according to the third embodiment of the present disclosure, each of the plurality of moisture permeable bypass portions 130 is provided in the form of the left lying “T”, thus the moisture permeation path can be lengthened by the first to second bypass members 1311a, 1311b, thereby delaying the permeation of moisture and oxygen. Thus, the transparent display apparatus 100 according to the second embodiment of the present disclosure can have an improved service life due to improved reliability against moisture permeation.

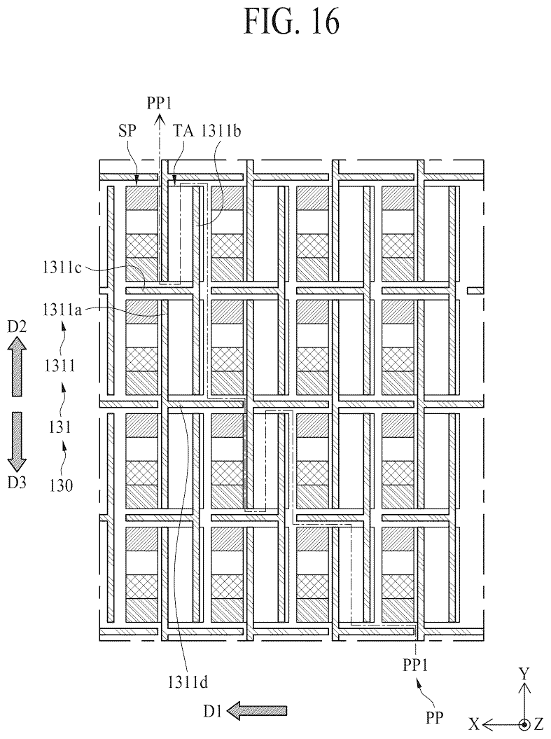

FIG. 16 is a schematic top view of a transparent display apparatus according to a fourth embodiment of the present disclosure.

Referring now to FIG. 16, the transparent display apparatus 100 according to the fourth embodiment of the present disclosure is identical to the transparent display device according to FIG. 1 described above, except that the structure of the plurality of moisture permeable bypass portions 130 (or the plurality of first moisture permeable bypass portions 131) has been changed. Accordingly, the same drawing symbols have been assigned to the same configurations, so that elements with different configurations will be focused and described hereinafter.

In the case of the transparent display apparatus according to FIG. 1 above, each of the plurality of moisture permeable bypass portions 130 is configured in the form of a double-T. For example, the first moisture permeable bypass portion 131 disposed in the first display area DA1 can be configured in the form of a left double-T. Thus, the transparent display device according to FIG. 1 can have a feature in which moisture permeation to the left upper direction in the first display area DA1 can be prevented more effectively than moisture permeation to the right upper direction.

In contrast, in the case of the transparent display device according to FIG. 16, each of the plurality of moisture permeable bypass portions 130 is configured in a structure in which the left lying “T” shape and the right lying “T” shape overlap in the perpendicular direction (or the first direction (Y-axis direction)). For example, the first moisture permeable bypass portion 131 disposed in the first display area DA1 includes the first bypass member 1311a, the second bypass member 1311b, the third bypass member 1311c, and the fourth bypass member 1311d. The first bypass member 1311a is disposed in the first direction (Y-axis direction), the second bypass member 1311b is disposed in parallel to the first bypass member 1311a and spaced apart from the first bypass member 1311a, the third bypass member 1311c is disposed in the second direction (X-axis direction) different from the first direction (Y-axis direction) and connecting to a point between two ends of the second bypass member 1311b, and the fourth bypass member 1311d is connecting to a point between two ends of the first bypass member 1311a and disposed in parallel to the third bypass member 1311c. Thus, in the case of the transparent display apparatus according to FIG. 16, each of the plurality of moisture permeable bypass portions 130 can be configured in a structure in which the left lying “T” shape and the right lying “T” shape are overlapped in the perpendicular direction (or the first direction (Y-axis direction)).

On the other hand, the first bypass member 1311a and the second bypass member 1311b can be disposed to extend in the first direction (Y-axis direction) from the transmissive portions TA of different pixels. Furthermore, each of the first bypass member 1311a and the second bypass member 1311b can be connected as one without being disconnected at the transmissive portions TA of each of the pixels adjacent to upper and lower. Each of the third bypass member 1311c and the fourth bypass member 1311d can be disposed to extend in the second direction (X-axis direction) between the upper and lower adjacent pixels. As shown in FIG. 16, the first bypass member 1311a and the second bypass member 1311b can only partially overlap in the second direction (X-axis direction). Also, the third bypass member 1311c and the fourth bypass member 1311d can only partially overlap in the first direction (Y-axis direction).

Accordingly, the transparent display apparatus 100 according to the fourth embodiment of the present description is configured in a structure in which each of the plurality of moisture permeable bypass portions 130 has the left lying “T” shape and the right lying “T” shape overlapping in a perpendicular direction (or the first direction (Y-axis direction)), thus the moisture permeable path PP (or the first moisture permeable path PP1) includes a path in the downward direction D3, as shown in FIG. 16, thereby extending the moisture permeable path.

As a result, the transparent display apparatus 100 according to the fourth embodiment of the present disclosure is configured in a structure in which each of the plurality of moisture permeable bypass portions 130 has the left lying “T” shape and the right lying “T” shape overlapping in a perpendicular direction (or a first direction (Y-axis direction)), thus the moisture permeation path by the first to fourth bypass members 1311a, 1311b, 1311c, 1311d can be lengthened, thereby delaying moisture and oxygen permeation. Thus, the transparent display apparatus 100 according to the fourth embodiment of the present disclosure can have an improved service life due to improved reliability against moisture permeation.

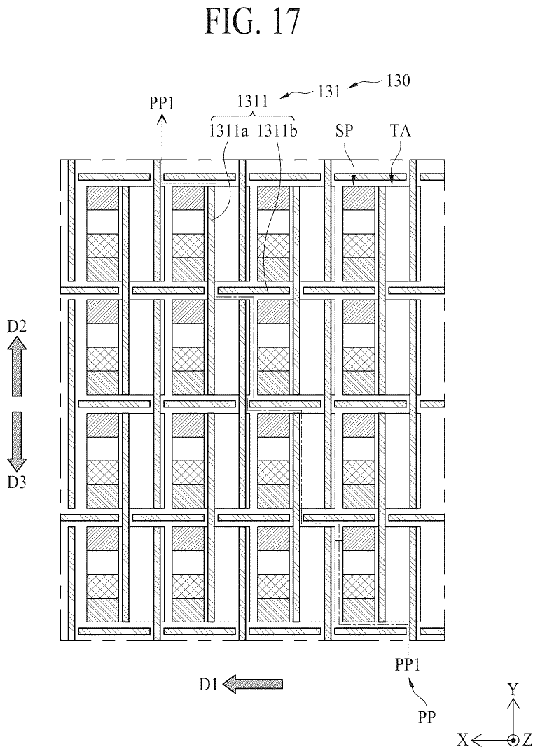

FIG. 17 is a schematic top view of a transparent display device according to a fifth embodiment of the present disclosure.

Referring now to FIG. 17, the transparent display apparatus 100 according to the fifth embodiment of the present disclosure is identical to the transparent display device according to FIG. 1 above, except that the structure of the plurality of moisture permeable bypass portions 130 (or the plurality of first moisture permeable bypass portions 131) has been changed. Accordingly, the same drawing symbols have been assigned to the same configurations, so that elements with different configurations will be focused and described hereinafter.

In the case of the transparent display apparatus according to FIG. 1 above, each of the plurality of moisture permeable bypass portions 130 is configured in a double T shape. For example, the first moisture permeable bypass portion 131 disposed in the first display area DA1 can be configured in the left double T shape. Thus, the transparent display apparatus according to FIG. 1 can have a feature in which moisture permeation to the left upper direction in the first display area DA1 can be prevented more effectively than moisture permeation to the right upper direction.

In contrast, in the case of the transparent display apparatus according to FIG. 17, each of the plurality of moisture permeable bypass portions 130 is provided with a combination of a horizontal straight line and a perpendicular straight line. For example, the first moisture permeable bypass portion 131 disposed in the first display area DA1 can include the first bypass member 1311a and the second bypass member 1311b. The first bypass member 1311a is disposed in the first direction (Y-axis direction), and the second bypass member 1311b is spaced apart from the first bypass member 1311a and disposed in the second direction (X-axis direction) different from the first direction (Y-axis direction). Here, the second bypass member 1311b can be disposed between two ends of the first bypass member 1311a with respect to the first direction (Y-axis direction). Thus, in the case of the transparent display apparatus according to FIG. 17, each of the plurality of moisture permeable bypass portions 130 can be provided with a combination of a horizontal straight line and a perpendicular straight line.

On the other hand, the first bypass member 1311a can be disposed to extend in the first direction (Y-axis direction) in the transmissive portions TA of different pixels. Further, the first bypass member 1311a can be connected as one without being disconnected at the transmissive portions TA of each of the pixels adjacent to upper and lower. The second bypass member 1311b can be disposed to extend in the second direction (X-axis direction) between the up and down neighboring pixels. As shown in FIG. 17, the second bypass member 1311b can be disposed between the sub-pixel of each of the upper and lower adjacent pixels, and a portion of the transmissive portion.

Therefore, the transparent display apparatus 100 according to the fifth embodiment of the present disclosure can have the moisture permeable bypass portion 130 in which each of the plurality of moisture permeable bypass portions 130 is configured in the form of a combination of a horizontal straight line and a perpendicular straight line, thus the moisture permeable path PP (or the first moisture permeable path PP1) can be extended as shown in FIG. 17. However, since the moisture permeation path PP (or the first moisture permeation path PP1) does not include a path in the downward direction D3, the moisture permeation path can be shorter compared to the transparent display device according to the first to fourth embodiments.

As a result, in the transparent display apparatus 100 according to the fifth embodiment of the present disclosure, each of the plurality of moisture permeable bypass portions 130 is provided with a combination of a horizontal straight line and a perpendicular straight line, thus the moisture permeable path by the first and second bypass members 1311a, 1311b is extended, thereby delaying the permeation of moisture and oxygen. Thus, the transparent display apparatus 100 according to the fifth embodiment of the present disclosure can have an improved service life due to improved reliability against moisture permeation.

On the other hand, the transparent display apparatus 100 according to one embodiment of the present disclosure can be configured to be divided into the first transparent display apparatus 101 and the second transparent display apparatus 102 when the cutting device cuts along the cutting portion CP. Each of the first transparent display apparatus 101 cut by the cutting device or the second transparent display apparatus 102 cut by the cutting device can include the substrate 110, the dam area 120, and the plurality of moisture permeable bypass portions 130. The substrate 110 is provided with the display area DA, in which the plurality of pixels P each having the transmissive portion TA and the plurality of sub-pixels SP are disposed, and the non-display area NDA on the periphery of the display area DA. The dam area 120 is surrounding the display area DA on the substrate 110, and the plurality of moisture permeable bypass portions 130 is disposed in the display area DA surrounded by the dam area 120.

The plurality of moisture permeable bypass portions 130 included in the first transparent display apparatus 101 cut by the cutting device is the same as the plurality of moisture permeable bypass portions 130 (or the plurality of first moisture permeable bypass portions 131) included in the transparent display apparatus 100 according to one embodiment of the present disclosure described above, and therefore, a description thereof will be omitted.

Furthermore, the plurality of moisture permeable bypass portions 130 included in the second transparent display apparatus 102 cut by the cutting device are the same as the plurality of moisture permeable bypass portions 130 (or the plurality of second moisture permeable bypass portions 132) included in the transparent display apparatus 100 according to one embodiment of the present disclosure described above, and therefore, a description thereof will be omitted.

As a result, the first transparent display apparatus 101 cut by the cutting device and the second transparent display apparatus 102 cut by the cutting device can be configured to have different areas (or different horizontal lengths and different perpendicular lengths). Also, since the first transparent display apparatus 101 can have the moisture permeable path lengthened by the plurality of first moisture permeable bypass portions 131, the reliability can be improved as well as the service life can be improved. Further, since the second transparent display apparatus 102 can have the moisture permeable path lengthened by the plurality of second moisture permeable bypass portions 132, reliability can be improved as well as a service life can be improved.

Embodiments of the present disclosure have been described in more detail with reference to the accompanying drawings, but the present disclosure is not necessarily limited to these embodiments and can be practiced in various modifications without departing from the technical ideas of the present disclosure. Accordingly, the embodiments disclosed herein are intended to illustrate and not to limit the technical ideas of the present disclosure, and the scope of the technical ideas of the present disclosure is not limited by these embodiments. Therefore, the embodiments described above are exemplary in all respects and should be understood as non-limiting. The scope of protection of this specification shall be construed by the claims, and all technical ideas within the scope of the claims shall be construed to be included within the scope of the claims.

According to various example, the present disclosure includes the plurality of dam areas to allow the display panel to be cut into various sizes, so that it can be manufactured in various types (or different sizes).

Further, according to various example, the present disclosure can be manufactured in various types (or different sizes) without additional masking processes, which can result in reduced production energy compared to transparent display devices produced in various types through different production processes.

Furthermore, according to various example, the present disclosure is provided with the island-shaped moisture permeable bypass portion such that the moisture path is disconnected, thus moisture permeation can be reduced or prevented even when manufactured in various types (or different sizes).

In addition, according to various example, the present disclosure is provided with the moisture permeable bypass portion including bypass members disposed in different directions to lengthen the moisture permeation path, thus moisture permeation can be reduced or prevented even though the bypass members are cut in different directions (or horizontal and perpendicular directions).

The effects that can be obtained from the present disclosure are not limited to those mentioned above, and other effects not mentioned will be apparent to one having ordinary skill in the art from the following description.

What is claimed is:

1. A transparent display apparatus comprising:
a substrate including a display area on which a plurality of pixels are disposed and a non-display area adjacent to the display area, each of the plurality of pixels having a transmissive portion and a plurality of sub-pixels; and
a plurality of dam areas extending from the non-display area to the display area on the substrate and partially surrounding the display area,
wherein the display area surrounded by each of the plurality of dam areas comprises a plurality of moisture permeable bypass portions.

2. The transparent display apparatus of claim 1, wherein the plurality of moisture permeable bypass portions are spaced apart from each other.

3. The transparent display apparatus of claim 1, wherein the plurality of moisture permeable bypass portions are disposed to overlap in at least one of a first direction and a second direction, the second direction being different from the first direction.

4. The transparent display apparatus of claim 1, further comprising:
a planarization layer disposed on the substrate;
a plurality of inorganic layers disposed between the substrate and the planarization layer; and
an undercut portion from which the planarization layer and the plurality of inorganic layers are partially removed,
wherein the undercut portion is disposed along an edge of each of the plurality of moisture permeable bypass portions.

5. The transparent display apparatus of claim 4, wherein each of the plurality of sub-pixels comprises:
an anode electrode disposed on the planarization layer;
an organic emitting layer disposed on the anode electrode;
a cathode electrode disposed on the organic emitting layer; and
an encapsulation layer disposed on the cathode electrode,
wherein the organic emitting layer is disconnected at the undercut portion.

6. The transparent display apparatus of claim 4,
wherein the substrate comprises a gate line covered by at least one of the plurality of inorganic layers, and
wherein the undercut portion comprises a blocking portion disposed on at least one inorganic layer covering the gate line.

7. The transparent display apparatus of claim 6, wherein the blocking portion partially overlaps the gate line.

8. The transparent display apparatus of claim 1,
wherein each of the plurality of moisture permeable bypass portions comprises a bypass member,
wherein the bypass member comprises:
a first bypass member disposed in a first direction;
a second bypass member spaced apart from the first bypass member and disposed parallel to the first bypass member;
a third bypass member disposed in a second direction different from the first direction and connecting the first bypass member and the second bypass member; and
a fourth bypass member disposed at one end of the first bypass member and disposed parallel to the third bypass member.

9. The transparent display apparatus of claim 8, wherein the third bypass member is connected to a point between two ends of the first bypass member and a point between two ends of the second bypass member.

10. The transparent display apparatus of claim 8, wherein the first bypass member is connected to a point between two ends of the fourth bypass member.

11. The transparent display apparatus of claim 1,
wherein each of the plurality of dam areas is provided in N numbers on the substrate, where N is an integer greater than 1, and
wherein the substrate further comprises a cutting portion provided between the N dam areas.

12. The transparent display apparatus of claim 11,
wherein the cutting portion comprises a first cutting line disposed in a first direction and a second cutting line disposed in a second direction different from the first direction,
wherein the first cutting line is disposed adjacent to a first side of the dam area, and
wherein the second cutting line is disposed adjacent to a second side of the dam area.

13. The transparent display apparatus of claim 12,
wherein the substrate further comprises a plurality of gate drivers disposed in the non-display area, and
wherein the plurality of gate drivers are disposed parallel to the first direction or the second direction.

14. The transparent display apparatus of claim 11,
wherein each of the plurality of sub-pixels disposed between the N dam areas comprises a light emission area disposed adjacent to the transmissive portion, and
wherein the cutting portion is disposed in at least one of the transmissive portion and/or the light emission area.

15. The transparent display apparatus of claim 1,
wherein each of the plurality of moisture permeable bypass portions comprises a bypass member,
wherein the bypass member comprises,
a first bypass member disposed in a first direction,
a second bypass member spaced apart from the first bypass member and disposed parallel to the first bypass member,
a third bypass member disposed in a second direction different from the first direction and connecting the first bypass member and the second bypass member, and
a fourth bypass member disposed at one end of the second bypass member and disposed parallel to the third bypass member.

16. The transparent display apparatus of claim 15, wherein the third bypass member is connected to a point between two ends of the first bypass member and a point between two ends of the second bypass member.

17. The transparent display apparatus of claim 15, wherein the second bypass member is connected to a point between two ends of the fourth bypass member.

18. The transparent display apparatus of claim 1,
wherein the plurality of dam areas comprise a first dam area and a second dam area,
wherein the first dam area is disposed in a first area of the substrate,
wherein the second dam area is disposed in a second area adjacent to the first area,
wherein the substrate comprises a reference line provided between the first area and the second area, and
wherein the first area has the same area as the second area with respect to the reference line.

19. The transparent display apparatus of claim 18,
wherein the display area comprises a first display area, a second display area, and a third display area,
wherein the first display area is surrounded by the first dam area,
wherein the second display area is surrounded by the second dam area, and
wherein the third display area is disposed between the first display area and the second display area and partially overlaps the reference line.

20. The transparent display apparatus of claim 19,
wherein the plurality of moisture permeable bypass portions comprise a first moisture permeable bypass portion and a second moisture permeable bypass portion,
wherein the first moisture permeable bypass portion is disposed in the first display area,
wherein the second moisture permeable bypass portion is disposed in the second display area, and
wherein the second moisture permeable bypass portion has a symmetrical shape with the first moisture permeable bypass portion with respect to the reference line.

21. The transparent display apparatus of claim 20,
wherein the third display area comprises a third moisture permeable bypass portion disposed between the first moisture permeable bypass portion and the second moisture permeable bypass portion, and
wherein the third moisture permeable bypass portion has a different shape from the first moisture permeable bypass portion and the second moisture permeable bypass portion.

22. The transparent display apparatus of claim 1,
wherein each of the plurality of moisture permeable bypass portions comprises a bypass member,
wherein the bypass member comprises,
a first bypass member disposed in a first direction,
a second bypass member spaced apart from the first bypass member and disposed parallel to the first bypass member,
a third bypass member disposed in a second direction different from the first direction and connecting the first bypass member and the second bypass member, and
a fourth bypass member spaced apart from the third bypass member and disposed parallel to the third bypass member and connecting the first bypass member and the second bypass member.

23. The transparent display apparatus of claim 22,
wherein the third bypass member is connected to one end of the first bypass member and a point between two ends of the second bypass member, and
wherein the fourth bypass member is connected to one end of the second bypass member and a point between two ends of the first bypass member.

24. The transparent display apparatus of claim 22,
wherein each of the plurality of moisture permeable bypass portions comprises a sealed area surrounded by a part of each of the first bypass member, the second bypass member, the third bypass member, and the fourth bypass member, and
wherein the sealed area is partially disposed on the transmissive portion.

25. The transparent display apparatus of claim 1,
wherein each of the plurality of moisture permeable bypass portions comprises a bypass member, and
wherein the bypass member comprises,
a first bypass member disposed in a first direction, and
a second bypass member disposed in a second direction different from the first direction and connected to a point between two ends of the first bypass member.

26. The transparent display apparatus of claim 1,
wherein each of the plurality of moisture permeable bypass portions comprises a bypass member, and
wherein the bypass member comprises:
a first bypass member disposed in a first direction, and
a second bypass member spaced apart from the first bypass member and disposed in a second direction different from the first direction.

27. The transparent display apparatus of claim 1,
wherein each of the plurality of moisture permeable bypass portions comprises a bypass member,
wherein the bypass member comprises;
a first bypass member disposed in a first direction,
a second bypass member spaced apart from the first bypass member and disposed parallel to the first bypass member,
a third bypass member disposed in a second direction different from the first direction and connected to a point between two ends of the second bypass member, and
a fourth bypass member connected a point between two ends of the first bypass member and disposed parallel to the third bypass member,
wherein the third bypass member is spaced apart from the first bypass member, and
wherein the fourth bypass member is spaced apart from the second bypass member.

28. A transparent display apparatus comprising:
a substrate including a display area on which a plurality of pixels are disposed and a non-display area adjacent to the display area, each of the plurality of pixels having a transmissive portion and a plurality of sub-pixels;
a dam area surrounding the display area on the substrate; and
a plurality of moisture permeable bypass portions disposed in the display area surrounded by the dam area.

29. The transparent display apparatus of claim 28, wherein the plurality of moisture permeable bypass portions are spaced apart from each other and partially overlaps in at least one of a first direction and a second direction different from the first direction.

30. The transparent display apparatus of claim 28, further comprising:
a planarization layer disposed on the substrate;
a plurality of inorganic layers disposed between the substrate and the planarization layer; and
an undercut portion from which the planarization layer and the plurality of inorganic layers are partially removed,
wherein the undercut portion is disposed along an edge of each of the plurality of moisture permeable bypass portions.

31. The transparent display apparatus of claim 30,
wherein each of the plurality of sub-pixels comprises:
an anode electrode disposed on the planarization layer,
an organic emitting layer disposed on the anode electrode,
a cathode electrode disposed on the organic emitting layer, and
an encapsulation layer disposed on the cathode electrode,
wherein the organic emitting layer is disconnected at the undercut portion.

32. The transparent display apparatus of claim 30,
wherein the substrate comprises a gate line covered by at least one of the plurality of inorganic layers, and
wherein the undercut portion comprises a blocking portion disposed to partially overlap the gate line on the at least one inorganic layer covering the gate line.

33. The transparent display apparatus of claim 28,
wherein each of the plurality of moisture permeable bypass portions comprises a bypass member, and
wherein the bypass member comprises:
a first bypass member disposed in a first direction,
a second bypass member spaced apart from the first bypass member and disposed parallel to the first bypass member,
a third bypass member disposed in a second direction different from the first direction and connecting the first bypass member and the second bypass member, and
a fourth bypass member disposed at one end of the first bypass member and disposed parallel to the third bypass member.

34. The transparent display apparatus of claim 33, wherein the third bypass member is connected to a point between two ends of the first bypass member and a point between two ends of the second bypass member.

35. The transparent display apparatus of claim 33, wherein the first bypass member is connected to a point between two ends of the fourth bypass member.

36. A transparent display apparatus comprising:
a substrate including a display area on which a plurality of pixels are disposed and a non-display area adjacent to the display area, each of the plurality of pixels having a transmissive portion and a plurality of sub-pixels,
wherein the display area comprises a plurality of moisture permeable bypass portions, the plurality of moisture permeable bypass portions being spaced apart from each other and at least partially overlapping in at least one of a first direction and a second direction different from the first direction.

37. The transparent display apparatus of claim 36, wherein each of the plurality of moisture permeable bypass portions comprises at least one bypass member disposed in the first direction and at least one bypass member disposed in the second direction.

38. The transparent display apparatus of claim 36, further comprising:
a planarization layer disposed on the substrate;
a plurality of inorganic layers disposed between the substrate and the planarization layer; and
an undercut portion from which the planarization layer and the plurality of inorganic layers are partially removed,
wherein the undercut portion is disposed along an edge of each of the plurality of moisture permeable bypass portions.
